(19) United States
(12) Patent Application Publication
(10) Pub. No.: US 2026/0169100 A1
(43) Pub. Date: Jun. 18, 2026

(54) MAGNETIC SENSOR, METHODS FOR MANUFACTURING AND DESIGNING SAME, AND MOTOR DEVICE

(71) Applicant: TDK CORPORATION, Tokyo (JP)

(72) Inventor: Tomoki HANADA, Tokyo (JP)

(73) Assignee: TDK CORPORATION, Tokyo (JP)

(21) Appl. No.: 19/382,544

(22) Filed: Nov. 7, 2025

(30) Foreign Application Priority Data
Dec. 13, 2024 (JP) 2024-218326

(51) Int. Cl. G01R 33/00; G01R 33/09; H02K 29/08

(52) U.S. Cl. CPC G01R 33/0023; G01R 33/0052; G01R 33/091; H02K 29/08

(57) ABSTRACT

A magnetic sensor includes at least one bridge circuit and a plurality of magnetoresistive elements. The at least one bridge circuit includes a first resistor section, a second resistor section, and a third resistor section. Each of the plurality of magnetoresistive elements includes a magnetization pinned layer having a magnetization whose direction is fixed. The plurality of magnetoresistive elements includes first, second, and third magnetoresistive elements constituting first, second, and third resistor sections, respectively. The direction of the magnetization of the magnetization pinned layer of the first magnetoresistive element, the direction of the magnetization of the magnetization pinned layer of the second magnetoresistive element, the direction of the magnetization of the magnetization pinned layer of the third magnetoresistive element intersect with one another at angles other than 0 degrees and 180 degrees.

### CROSS REFERENCE TO RELATED APPLICATIONS

This application claims the benefit of Japanese Priority Patent Application No. 2024-218326 filed on Dec. 13, 2024, the entire contents of which are incorporated herein by reference.

### BACKGROUND

The disclosure relates to a magnetic sensor configured to detect a rotation angle of a motor, methods for manufacturing and designing the same, and a motor device including the motor and the magnetic sensor.

A brushless motor (also referred to as a brushless direct-current [DC] motor) uses an angle detector to detect a rotation angle of the brushless motor. Known examples of the angle detector include a detector using a magnetic detection element such as a Hall element, and an optical detector using light. The detection signal of the angle detector is used for feedback control of the rotation angle and/or rotation speed of the brushless motor.

A brushless motor is typically a three-phase motor driven by a three-phase alternating-current voltage. A three-phase motor includes a plurality of coils controlled so that voltages are applied at respective different timings. When the three-phase motor includes three coils, the voltage application timings can be controlled by using three logic signals (signals each indicating two states “high” and “low”) with 120-degree different phases. The detection signal of the angle detector is used to generate the three logic signals. To generate the three logic signals by the angle detector using Hall elements, it is required to arrange the Hall elements at three positions within the brushless motor.

Incidentally, in addition to the Hall element, a spin-valve magnetoresistive element has been known as the magnetic detection element. The spin-valve magnetoresistive element includes a magnetization pinned layer having a magnetization whose direction is fixed, a free layer having a magnetization whose direction is variable depending on a direction of an applied magnetic field, and a gap layer arranged between the magnetization pinned layer and the free layer.

International Publication No. 2016/083420, JP 2022-111711 A, and JP 2013-88232 A each disclose a magnetic sensor using a spin-valve magnetoresistive element. Further, International Publication No. 2016/083420 discloses a magnetoresistive wheatstone bridge including a plurality of resistors whose pinning directions are set in respective different directions.

Here, it is contemplated to use a magnetic sensor using a spin-valve magnetoresistive element for rotation control of a motor. In this case, it is contemplated to configure the magnetic sensor so as to generate two detection signals having respective different phases and to generate three logic signals by using the two detection signals. When a direction of a magnetic field to be detected by the magnetic sensor changes at a predetermined angular speed, waveforms of the two detection signals are, ideally, sine curves (including a sine waveform and a cosine waveform). However, when the magnetic sensor is arranged in a brushless motor, waveforms of the two detection signals may be greatly distorted from sine curves. In this case, it is not possible to generate the three logic signals with a predetermined phase difference.

### SUMMARY

A magnetic sensor according to one embodiment of the disclosure includes at least one bridge circuit and a plurality of magnetoresistive elements. The at least one bridge circuit includes a first port, a second port, a third port, a fourth port, a first resistor section provided between the first port and the second port, a second resistor section provided between the second port and the third port, a third resistor section provided between the third port and the fourth port, and a fourth resistor section provided between the fourth port and the first port. Each of the plurality of magnetoresistive elements includes a magnetization pinned layer having a magnetization whose direction is fixed and a free layer having a magnetization whose direction is variable depending on a magnetic field to be applied. The plurality of magnetoresistive elements includes a plurality of first magnetoresistive elements constituting the first resistor section, a plurality of second magnetoresistive elements constituting the second resistor section, a plurality of third magnetoresistive elements constituting the third resistor section, and a plurality of fourth magnetoresistive elements constituting the fourth resistor section. The first resistor section, the second resistor section, and the third resistor section are configured so that a first magnetization direction, a second magnetization direction, and a third magnetization direction intersect with one another at angles other than 0 degrees and 180 degrees, the first magnetization direction being a direction obtained by averaging magnetization directions of the plurality of magnetization pinned layers included in the plurality of first magnetoresistive elements, the second magnetization direction being a direction obtained by averaging magnetization directions of the plurality of magnetization pinned layers included in the plurality of second magnetoresistive elements, the third magnetization direction being a direction obtained by averaging magnetization directions of the plurality of magnetization pinned layers included in the plurality of third magnetoresistive elements.

A motor device according to one embodiment of the disclosure includes a motor, a driving circuit for the motor, and the magnetic sensor according to the one embodiment of the disclosure. The magnetic sensor is connected to the driving circuit.

A method for manufacturing a magnetic sensor according to one embodiment of the disclosure includes an element formation step of forming the plurality of magnetoresistive elements. The element formation step includes a step of forming a stacked film including a plurality of first magnetic sections that later serve as a plurality of magnetization pinned layers and a plurality of second magnetic sections that later serve as a plurality of free layers and a fixation step of fixing a magnetization direction of each of the plurality of first magnetic sections by using laser light and an external magnetic field. The fixation step includes a first step of fixing magnetization directions of a plurality of first specific magnetic sections, among the plurality of first magnetic sections, which later serve as a plurality of magnetization pinned layers of the plurality of first magnetoresistive elements, a second step of fixing magnetization directions of a plurality of second specific magnetic sections, among the plurality of first magnetic sections, which later serve as a plurality of magnetization pinned layers of the plurality of second magnetoresistive elements, and a third step of fixing magnetization directions of a plurality of third specific magnetic sections, among the plurality of first magnetic sections, which later serve as a plurality of magnetization pinned layers of the plurality of third magnetoresistive elements. A direction of the external magnetic field in the first step, a direction of the external magnetic field in the second step, and a direction of the external magnetic field in the third step intersect with one another at angles other than 0 degrees and 180 degrees.

A magnetic sensor that is designed by a designing method according to one embodiment of the disclosure includes a bridge circuit and a plurality of magnetoresistive elements. The bridge circuit includes a first port, a second port, a third port, a fourth port, a first resistor section provided between the first port and the second port, a second resistor section provided between the second port and the third port, a third resistor section provided between the third port and the fourth port, and a fourth resistor section provided between the fourth port and the first port. Each of the plurality of magnetoresistive elements includes a magnetization pinned layer having a magnetization whose direction is fixed and a free layer having a magnetization whose direction is variable depending on a magnetic field to be applied. The plurality of magnetoresistive elements includes a plurality of first magnetoresistive elements constituting the first resistor section, a plurality of second magnetoresistive elements constituting the second resistor section, a plurality of third magnetoresistive elements constituting the third resistor section, and a plurality of fourth magnetoresistive elements constituting the fourth resistor section. The bridge circuit is configured to detect a rotating magnetic field whose direction rotates at a detection position.

The designing method according to one embodiment of the disclosure includes setting directions of magnetizations of a plurality of magnetization pinned layers included in each of the plurality of first magnetoresistive elements, the plurality of second magnetoresistive elements, the plurality of third magnetoresistive elements, and the plurality of fourth magnetoresistive elements so that the bridge circuit generates a first detection signal and a second detection signal each corresponding to a change of the direction of the rotating magnetic field, and setting the directions of the magnetizations of the plurality of magnetization pinned layers so that a temporal period corresponding to one rotation in the direction of the rotating magnetic field is divided into three or more temporal sub-periods, based on the first detection signal and the second detection signal.

Objects, features, and advantages of the disclosure will appear more fully from the following description.

### BRIEF DESCRIPTION OF THE DRAWINGS

The accompanying drawings are included to provide a further understanding of the disclosure, and are incorporated in and constitute a part of this specification. The drawings illustrate example embodiments and, together with the specification, serve to explain the principles of the technology.

FIG. 1 is an explanatory diagram showing a configuration of a motor device according to a first example embodiment of the disclosure.

FIG. 2 is a plan view showing a part of the motor device according to the first example embodiment of the disclosure.

FIG. 3 is an explanatory diagram showing an interior of a magnetic sensor according to the first example embodiment of the disclosure.

FIG. 4 is a circuit diagram showing a circuit configuration of the magnetic sensor according to the first example embodiment of the disclosure.

FIG. 5 is an explanatory diagram showing definitions of directions and angles in the first example embodiment of the disclosure.

FIG. 6 is a perspective view showing some of resistor sections in the first example embodiment of the disclosure.

FIG. 7 is a waveform chart showing a waveform of each of first and second detection signals in the first example embodiment of the disclosure.

FIG. 8 is a timing chart showing first to third logic signals in the first example embodiment of the disclosure.

FIG. 9 is a flowchart showing a method for manufacturing a magnetic sensor according to the first example embodiment of the disclosure.

FIG. 10 is a flowchart showing a method for designing a magnetic sensor according to the first example embodiment of the disclosure.

FIG. 11 is a circuit diagram showing a circuit configuration of a magnetic sensor in a comparative example.

FIG. 12 is a waveform chart showing a waveform of each of first and second detection signals in the comparative example.

FIG. 13 is a waveform chart showing a waveform of each of the first and second detection signals in a first modification example of the magnetic sensor according to the first example embodiment of the disclosure.

FIG. 14 is a waveform chart showing a waveform of each of the first and second detection signals in a second modification example of the magnetic sensor according to the first example embodiment of the disclosure.

FIG. 15 is a waveform chart showing a waveform of each of the first and second detection signals in a third modification example of the magnetic sensor according to the first example embodiment of the disclosure.

FIG. 16 is a circuit diagram showing a circuit configuration of a magnetic sensor according to a second example embodiment of the disclosure.

FIG. 17 is a waveform chart showing a waveform of each of the first and second detection signals according to the second example embodiment of the disclosure.

### DETAILED DESCRIPTION

An object of the disclosure is to provide a magnetic sensor capable of generating a detection signal that can be used for rotation control of a motor, methods for manufacturing and designing the same, and a motor device including the magnetic sensor.

Example embodiments and modification examples of the disclosure are described below in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

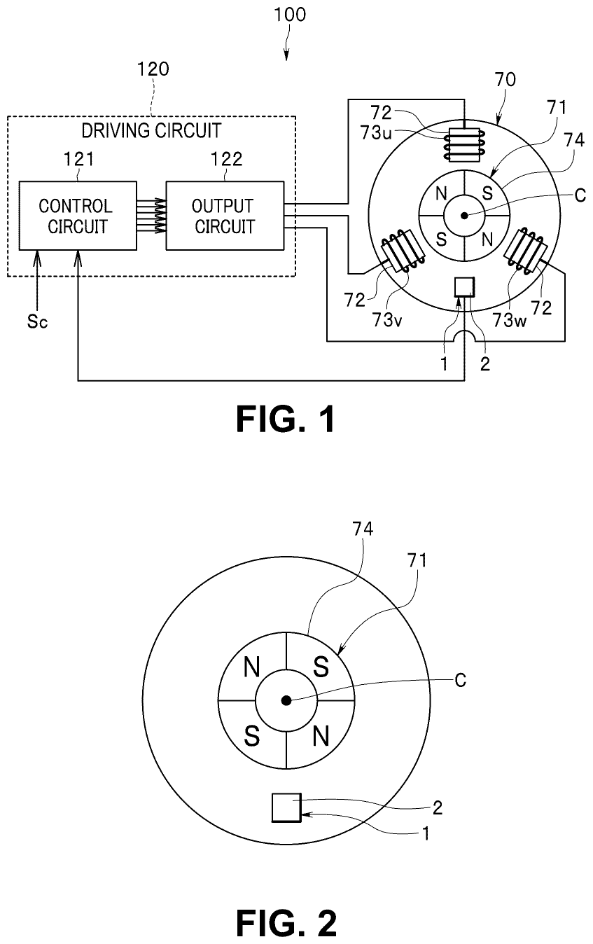

First, with reference to FIGS. 1 and 2, a schematic configuration of a motor device according to a first example embodiment of the disclosure is described. FIG. 1 is an explanatory diagram showing a configuration of a motor device 100 according to the example embodiment. FIG. 2 is a plan view showing a part of the motor device 100.

The motor device 100 according to the example embodiment includes the magnetic sensor 1 according to the example embodiment, the motor 70, and a driving circuit 120 that drives the motor 70. The motor 70 is a three-phase brushless motor (also referred to as a brushless DC motor), for example. The following description is given by using a case where the motor 70 is a three-phase brushless motor as an example. In such a case, the motor 70 includes a not-shown shaft configured to rotate about a rotation axis C, a rotor 71 fixed to the not-shown shaft, a stator 72, and a plurality of coils.

FIG. 1 shows an example where the stator 72 has three slots. In this example, the motor 70 includes a first coil 73u, a second coil 73v, and a third coil 73w as the plurality of coils. The first coil 73u, the second coil 73v, and the third coil 73w are also referred to as a U-phase coil, a V-phase coil, and a W-phase coil, respectively. The first coil 73u, the second coil 73v, and the third coil 73w are arranged about the rotation axis C at intervals of 120 degrees.

The rotor 71 is configured by a magnetic field generator 74 that generates a magnetic field. FIGS. 1 and 2 show a multi-pole magnet in which one or more pairs of N poles and S poles are alternately arranged in a ring shape as one example of the magnetic field generator 74. Note that, in the example shown in FIGS. 1 and 2, the magnetic field generator 74 is a four-pole magnet including two pairs of N poles and S poles.

Note that the number of slots of the stator 72 is not limited to three, and may be greater than three, for example, six or nine. The magnetic field generator 74 may be a cylindrical bipolar magnet with an N pole and an S pole symmetrically arranged about an imaginary plane including the rotation axis C. When the magnetic field generator 74 is a multi-pole magnet, the number of poles of the magnetic field generator 74 is not limited to four, and may be eight.

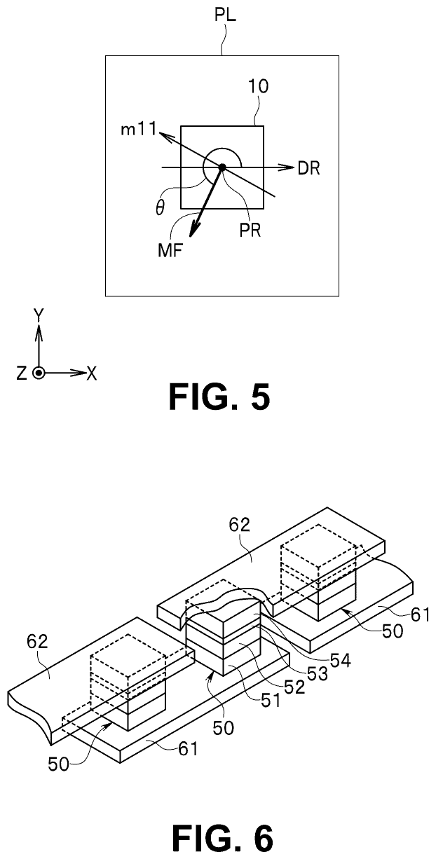

The direction of the magnetic field generated by the magnetic field generator 74 rotates with the rotation of the motor 70, in other words, the rotation of the not-shown shaft. Hereinafter, the magnetic field generated by the magnetic field generator 74 is referred to as a rotating magnetic field MF. The rotating magnetic field MF is shown in FIG. 5 to be described later. In a case where n is an integer of 1 or more, when the magnetic field generator 74 is a magnet having 2n poles, the rotating magnetic field MF rotates n times while the rotor 71 rotates once. The magnetic sensor 1 is configured to detect the rotating magnetic field MF and generate three logic signals to be used to control the timing of voltage applied to the first to third coils 73u, 73v, and 73w. In the example embodiment, the magnetic sensor 1 is arranged at a position away from the rotation axis C. For example, the magnetic sensor 1 is arranged outside the outer peripheral of the magnetic field generator 74. The configuration of the magnetic sensor 1 is described later in detail.

The driving circuit 120 includes a control circuit 121 and an output circuit 122. The control circuit 121 is configured so that the three logic signals generated by the magnetic sensor 1 and a speed command Sc from outside are input thereto. The control circuit 121 controls the output circuit 122, based on the three logic signals and the speed command Sc. The output circuit 122 applies a voltage to each of the first to third coils 73u, 73v, and 73w, based on commands from the control circuit 121.

The output circuit 122 includes not-shown six switching elements. Each of the six switching elements includes a transistor, for example. The control circuit 121 controls the six switching elements on and off, and thereby controls the timing of voltage application to each of the first to third coils 73u, 73v, and 73w so that a magnetic field into which the magnetic fields generated by the first to third coils 73u, 73v, and 73w are combined (hereinafter, referred to as a composite magnetic field) rotates. The timing is controlled based on the three logic signals. The rotor 71 rotates due to the interaction of the magnetic field (rotating magnetic field MF) generated by the magnetic field generator 74 and the composite magnetic field.

The control circuit 121 compares the speed command Sc and the rotation speed of the motor 70 obtained from the three logic signals, and controls the output circuit 122 so that the rotation speed of the motor 70 follows the speed command Sc.

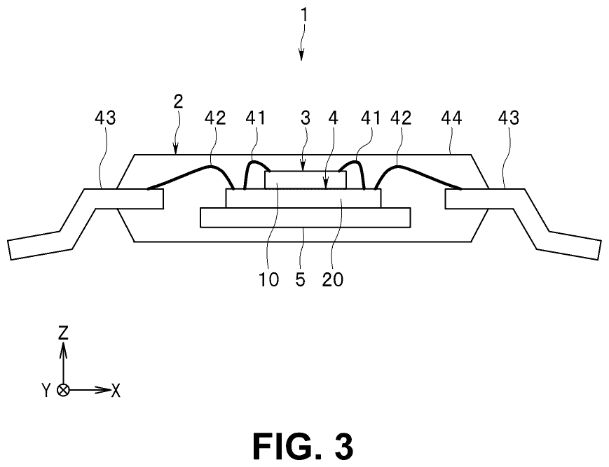

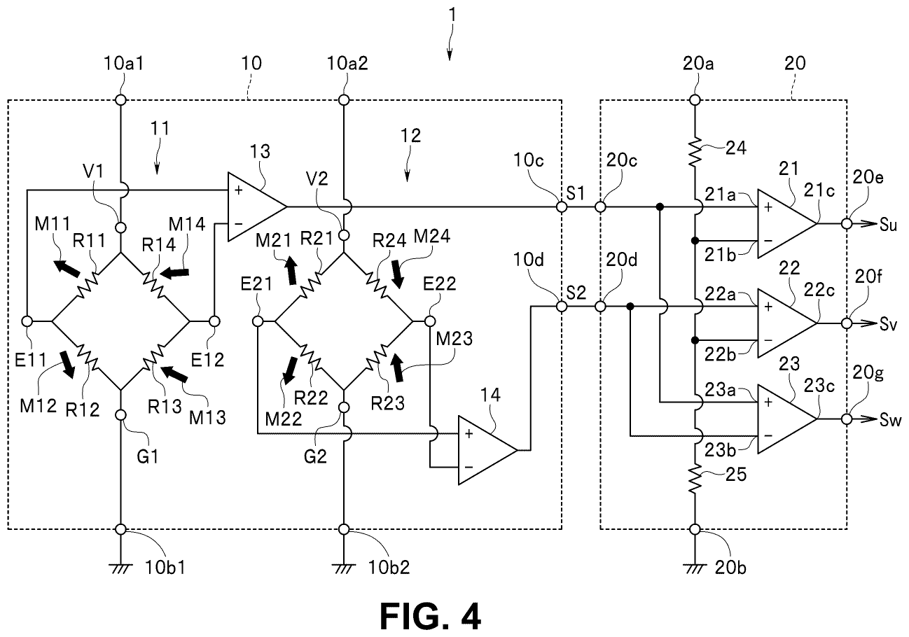

Next, with reference to FIGS. 3 and 4, the magnetic sensor 1 is described in detail. FIG. 3 is an explanatory diagram showing an interior of the magnetic sensor 1. FIG. 4 is a circuit diagram showing a circuit configuration of the magnetic sensor 1.

First, a schematic configuration of the magnetic sensor 1 is described. As described above, the magnetic sensor 1 is used for the driving circuit 120 for the motor 70. The magnetic sensor 1 may include a detection circuit 10 and a logic signal generation circuit 20. The detection circuit 10 and the logic signal generation circuit 20 may be each configured as a chip having a rectangular solid shape. Hereinafter, the chip including the detection circuit 10 is referred to as a first chip 3, and the chip including the logic signal generation circuit 20 is referred to as a second chip 4. The magnetic sensor 1 includes the first chip 3 and the second chip 4.

As shown in FIG. 3, one of the first chip 3 and the second chip 4 is mounted on the other of the first chip 3 and the second chip 4. The magnetic sensor 1 further includes a substrate 5. In particular, in the example embodiment, the second chip 4 is mounted on the substrate 5, and the first chip 3 is mounted on the second chip 4.

The magnetic sensor 1 further includes a plurality of wires 41 and 42 and a plurality of leads 43. The plurality of wires 41 connect the first chip 3 and the second chip 4 to each other. The plurality of wires 42 connect the second chip 4 and the plurality of leads 43.

The magnetic sensor 1 may further include a main body 2 in which the first chip 3 and the second chip 4 are embedded. The main body 2 includes a sealing resin 44 that seals the first chip 3 and the second chip 4. The plurality of leads 43 extend outward from the sealing resin 44.

Note that the logic signal generation circuit 20 (the second chip 4) may not be embedded in the main body 2. In such a case, the logic signal generation circuit 20 may be arranged at a position different from the main body 2.

Next, a configuration of the detection circuit 10 is described. The detection circuit 10 is configured to detect a physical quantity changing periodically in response to the rotation angle of the motor 70 and output a first detection signal S1 and a second detection signal S2. In the example embodiment, the physical quantity is the rotating magnetic field MF generated by the magnetic field generator 74. The direction of the rotating magnetic field MF rotates with the rotation angle of the motor 70.

Here, with reference to FIGS. 1, 3, and 5, the definitions of directions and angles in the example embodiment are described. FIG. 5 is an explanatory diagram showing the definitions of directions and angles in the example embodiment. First, one direction parallel to the rotation axis C shown in FIG. 1 is defined as a Z direction. In FIG. 3, the Z direction is shown as an upward direction. In FIG. 5, the Z direction is shown as a direction from the far to near side of FIG. 5. As shown in FIG. 3, the first chip 3 (detection circuit 10) and the second chip 4 (logic signal generation circuit 20) are stacked in the Z direction.

Next, two directions perpendicular to the Z direction and orthogonal to each other are defined as an X direction and a Y direction. In FIGS. 3 and 5, the X direction is shown as a rightward direction. In FIG. 3, the Y direction is shown as a direction from the near to far side of FIG. 3. In FIG. 5, the Y direction is shown as an upward direction. The direction opposite to the X direction is defined as a −X direction, the direction opposite to the Y direction a −Y direction, and the direction opposite to the Z direction a −Z direction.

In FIG. 5, the symbol PL denotes an imaginary plane perpendicular to the rotation axis C. Hereinafter, this imaginary plane is referred to as a reference plane PL. In the example embodiment, the detection circuit 10 is configured to detect the components of the rotating magnetic field MF in directions parallel to the reference plane PL, at a reference position PR within the reference plane PL. In FIG. 5, the symbol PL denotes an imaginary plane perpendicular to the rotation axis C. The reference position PR is at a position away from the rotation axis C (for example, a position at which the magnetic sensor 1 is arranged).

In FIG. 5, the direction of the rotating magnetic field MF is indicated by the arrow denoted by the symbol MF. In the example embodiment, the direction of the rotating magnetic field MF is expressed as an angle (hereinafter, referred to as a rotating magnetic field angle) θ formed with a reference direction DR. The reference direction DR is the X direction. The direction of the rotating magnetic field MF rotates counterclockwise in FIG. 5. The rotating magnetic field angle θ is represented by a positive value when seen counterclockwise from the reference direction DR, and by a negative value when seen clockwise from the reference direction DR.

The detection circuit 10 includes at least one bridge circuit and a plurality of magnetoresistive elements (hereinafter, referred to as MR elements) 50. The at least one bridge circuit includes a plurality of resistor sections including the plurality of MR elements 50. The at least one bridge circuit may be a Wheatstone bridge circuit (full bridge circuit) including four resistor sections, or may be a circuit including two half-bridge circuits each including two resistor sections. The at least one bridge circuit further includes four ports. Each of the four resistor sections is provided between two arbitrary ports of the four ports.

In particular, in the example embodiment, the detection circuit 10 includes a first bridge circuit 11 and a second bridge circuit 12 as the at least one bridge circuit. Each of the first and second bridge circuits 11 and 12 is a Wheatstone bridge circuit.

The first bridge circuit 11 includes a power supply port V1, a ground port G1, a first output port E11, a second output port E12, a first resistor section R11, a second resistor section R12, a third resistor section R13, and a fourth resistor section R14. The first resistor section R11 is provided between the power supply port V1 and the first output port E11 in the circuit configuration. The second resistor section R12 is provided between the ground port G1 and the first output port E11 in the circuit configuration. The third resistor section R13 is provided between the ground port G1 and the second output port E12 in the circuit configuration. The fourth resistor section R14 is provided between the power supply port V1 and the second output port E12 in the circuit configuration. Note that, in the present application, the expression “in a (the) circuit configuration” is used to indicate a layout in a circuit diagram and not a layout in a physical configuration.

The second bridge circuit 12 includes a power supply port V2, a ground port G2, a first output port E21, a second output port E22, a first resistor section R21, a second resistor section R22, a third resistor section R23, and a fourth resistor section R24. The first resistor section R21 is provided between the power supply port V2 and the first output port E21 in the circuit configuration. The second resistor section R22 is provided between the ground port G2 and the first output port E21 in the circuit configuration. The third resistor section R23 is provided between the ground port G2 and the second output port E22 in the circuit configuration. The fourth resistor section R24 is provided between the power supply port V2 and the second output port E22 in the circuit configuration.

The detection circuit 10 further includes power supply terminals 10a1 and 10a2, ground terminals 10b1 and 10b2, a first output terminal 10c, a second output terminal 10d, a first differential amplifier 13, and a second differential amplifier 14.

The power supply ports V1 and V2 are connected to the power supply terminals 10a1 and 10a2, respectively. The ground ports G1 and G2 are connected to the ground terminals 10b1 and 10b2, respectively. A voltage or current of a specific magnitude is applied to each of the power supply terminals 10a1 and 10a2. Each of the ground terminals 10b1 and 10b2 is grounded.

The first differential amplifier 13 includes two input ends and one output end. The first and second output ports E11 and E12 are connected to the two input ends of the first differential amplifier 13. The output end of the first differential amplifier 13 is connected to the first output terminal 10c. The first differential amplifier 13 generates a signal corresponding to a potential difference between the first and second output ports E11 and E12 as the first detection signal S1. The first output terminal 10c outputs the first detection signal S1.

The second differential amplifier 14 includes two input ends and one output end. The first and second output ports E21 and E22 are connected to the two input ends of the second differential amplifier 14. The output end of the second differential amplifier 14 is connected to the second output terminal 10d. The second differential amplifier 14 generates a signal corresponding to a potential difference between the first and second output ports E21 and E22 as the second detection signal S2. The second output terminal 10d outputs the second detection signal S2.

Here, the MR element 50 is described in detail. In the example embodiment, the MR element 50 is a spin-valve MR element. The spin-valve MR element includes a magnetization pinned layer having a magnetization whose direction is fixed, a free layer having a magnetization whose direction is variable depending on the rotating magnetic field MF, and a gap layer arranged between the magnetization pinned layer and the free layer. The spin-valve MR element may be a tunnel magnetoresistive (TMR) element, or may be a giant magnetoresistive (GMR) element. In the TMR element, the gap layer is a tunnel barrier layer. In the GMR element, the gap layer is a nonmagnetic conductive layer. The spin-valve MR element varies in resistance according to the angle that the magnetization direction of the free layer forms with the magnetization direction of the magnetization pinned layer, and has a minimum resistance when the foregoing angle is 0 degrees and a maximum resistance when the foregoing angle is 180 degrees.

FIG. 6 is a perspective view showing a part of any one of the resistor sections R11 to R14 and R21 to R24. The arbitrary resistor section includes a plurality of lower electrodes 61, a plurality of MR elements 50, and a plurality of upper electrodes 62. The plurality of lower electrodes 61 are arranged on a not-shown substrate. Each of the lower electrodes 61 has an elongated shape. There is a gap formed between two lower electrodes 61 adjacent to each other in the longitudinal direction of the lower electrode 61. As shown in FIG. 6, the MR elements 50 are arranged in the vicinities of both the ends of the top surface of the lower electrode 61 in the longitudinal direction.

The MR element 50 includes an antiferromagnetic layer 51, a magnetization pinned layer 52, a gap layer 53, and a free layer 54 that are stacked in the stated order from the lower electrode 61 side. The antiferromagnetic layer 51 is electrically connected to the lower electrode 61. The antiferromagnetic layer 51 is made of an antiferromagnetic material. The antiferromagnetic layer 51 generates an exchange coupling with the magnetization pinned layer 52 to fix the magnetization direction of the magnetization pinned layer 52. The plurality of upper electrodes 62 are arranged on the plurality of MR elements 50. Each of the upper electrodes 62 has an elongated shape, and electrically connects the free layers 54 of two adjacent MR elements 50 arranged on two lower electrodes 61 that are adjacent to each other in the longitudinal direction of the lower electrode 61. With such a configuration, the resistor section shown in FIG. 6 includes the plurality of MR elements 50 connected in series by the plurality of lower electrodes 61 and the plurality of upper electrodes 62.

Note that the magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In a case where the magnetization pinned layer 52 is a self-pinned layer, the antiferromagnetic layer 51 may be omitted.

The layers 51 to 54 of each of the MR elements 50 may be stacked in the reverse order to that shown in FIG. 6.

Next, description is made on the magnetization direction of the magnetization pinned layer 52 in each of the first to fourth resistor sections R11 to R14 of the first bridge circuit 11 and sensitivity of each of the first to fourth resistor sections R11 to R14. The plurality of MR elements 50 include a plurality of first MR elements 50A1 constituting the first resistor section R11, a plurality of second MR elements 50B1 constituting the second resistor section R12, a plurality of third MR elements 50C1 constituting the third resistor section R13, and a plurality of fourth MR elements 50D1 constituting the fourth resistor section R14.

Here, a direction obtained by averaging the magnetization directions of the plurality of magnetization pinned layers 52 included in the plurality of first MR elements 50A1 is referred to as a first magnetization direction m11, a direction obtained by averaging the magnetization directions of the plurality of magnetization pinned layers 52 included in the plurality of second MR elements 50B1 is referred to as a second magnetization direction m12, a direction obtained by averaging the magnetization directions of the plurality of magnetization pinned layers 52 included in the plurality of third MR elements 50C1 is referred to as a third magnetization direction m13, and a direction obtained by averaging the magnetization directions of the plurality of magnetization pinned layers 52 included in the plurality of fourth MR elements 50D1 is referred to as a fourth magnetization direction m14.

The magnetization direction of each of the plurality of magnetization pinned layers 52 included in the plurality of first MR elements 50A1 may match with the first magnetization direction m11. Alternatively, as long as the requirement that the direction obtained by averaging the magnetization directions of the plurality of magnetization pinned layers 52 is the first magnetization direction m11 is satisfied, the magnetization direction in at least some of the plurality of magnetization pinned layers 52 may not match with the first magnetization direction m11.

The description given above on the plurality of first MR elements 50A1 is also applicable to the plurality of second MR elements 50B1, the plurality of third MR elements 50C1, and the plurality of fourth MR elements 50D1.

Three resistor sections of the first to fourth resistor sections R11 to R14 are configured so that three magnetization directions corresponding to the three resistor sections intersect with one another at angles other than 0 degrees and 180 degrees. The other resistor section of the first to fourth resistor sections R11 to R14 may be configured so that a magnetization direction corresponding to the other resistor section intersects with each of the above-mentioned three magnetization directions at angles other than 0 degrees and 180 degrees or is the same direction as any one of the above-mentioned three magnetization directions. In particular, in the example embodiment, the first to fourth resistor sections R11 to R14 are configured so that the first to fourth magnetization directions m11 to m14 intersect with one another at angles other than 0 degrees and 180 degrees.

The first resistor section R11 has sensitivity in a first direction parallel to a first reference direction M11. The second resistor section R12 has sensitivity in a second direction parallel to a second reference direction M12. The third resistor section R13 has sensitivity in a third direction parallel to a third reference direction M13. The fourth resistor section R14 has sensitivity in a fourth direction parallel to a fourth reference direction M14. In FIG. 4, the first to fourth reference directions M11 to M14 are indicated by the arrows denoted with the reference symbols M11 to M14, respectively.

The three resistor sections of the first to fourth resistor sections R11 to R14 may be configured so that three sensitivity directions (three reference directions) corresponding to the three resistor sections intersect with one another at angles other than 0 degrees and 180 degrees. The other resistor section of the first to fourth resistor sections R11 to R14 may be configured so that a sensitivity direction corresponding to the other resistor section intersects with each of the above-mentioned three sensitivity directions (the three reference directions) at angles other than 0 degrees and 180 degrees or is the same direction as any one of the above-mentioned three sensitive directions (the three reference directions). In the example shown in FIG. 4, the first to fourth resistor sections R11 to R14 are configured so that the first to fourth directions (the first to fourth reference directions M11 to M14) intersect with one another at angles other than 0 degrees and 180 degrees.

The first reference direction M11 may match with the first magnetization direction m11, or may be different from the first magnetization direction m11. When the first reference direction M11 is different from the first magnetization direction m11, the first resistor section R11 may include at least one MR element 50 including the magnetization pinned layer 52 having a magnetization direction different from the first magnetization direction m11, in addition to the plurality of first MR elements 50A1. In the following description, it is assumed that the first reference direction M11 matches with the first magnetization direction m11.

The description given above on the pair of the first reference direction M11 and the first magnetization direction m11 is also applicable to the pair of the second reference direction M12 and the second magnetization direction m12, the pair of the third reference direction M13 and the third magnetization direction m13, and the pair of the fourth reference direction M14 and the fourth magnetization direction m14. In the following description, it is assumed that the second reference direction M12 matches with the second magnetization direction m12, the third reference direction M13 matches with the third magnetization direction m13, and the fourth reference direction M14 matches with the fourth magnetization direction m14.

Next, description is made on the magnetization direction of the magnetization pinned layer 52 in each of the first to fourth resistor sections R21 to R24 of the second bridge circuit 12 and sensitivity of each of the first to fourth resistor sections R21 to R24. The plurality of MR elements 50 further includes a plurality of first MR elements 50A2 constituting the first resistor section R21, a plurality of second MR elements 50B2 constituting the second resistor section R22 a plurality of third MR elements 50C2 constituting the third resistor section R23, and a plurality of fourth MR elements 50D2 constituting the fourth resistor section R24.

Here, a direction obtained by averaging the magnetization directions of the plurality of magnetization pinned layers 52 included in the plurality of first MR elements 50A2 is referred to as a first magnetization direction m21, a direction obtained by averaging the magnetization directions of the plurality of magnetization pinned layers 52 included in the plurality of second MR elements 50B2 is referred to as a second magnetization direction m22, a direction obtained by averaging the magnetization directions of the plurality of magnetization pinned layers 52 included in the plurality of third MR elements 50C2 is referred to as a third magnetization direction m23, and a direction obtained by averaging the magnetization directions of the plurality of magnetization pinned layers 52 included in the plurality of fourth MR elements 50D2 is referred to as a fourth magnetization direction m24.

The description given above on the first to fourth magnetization directions m11 to m14 is also applicable to the first to fourth magnetization directions m21 to m24. The first to fourth resistor sections R11 to R14 and the first to fourth magnetization directions m11 to m14 in the description on the first to fourth magnetization directions m11 to m14 are replaced with the first to fourth resistor sections R21 to R24 and the first to fourth magnetization directions m21 to m24, respectively. With this, the description on the first to fourth magnetization directions m21 to m24 is given.

The first resistor section R21 has sensitivity in a first direction parallel to a first reference direction M21. The second resistor section R22 has sensitivity in a second direction parallel to a second reference direction M22. The third resistor section R23 has sensitivity in a third direction parallel to a third reference direction M23. The fourth resistor section R24 has sensitivity in a fourth direction parallel to a fourth reference direction M24. In FIG. 4, the first to fourth reference directions M21 to M24 are indicated by the arrows denoted with the reference symbols M21 to M24, respectively.

The description given above on the first to fourth directions of the first to fourth resistor sections R11 to R14 is also applicable to the first to fourth directions of the first to fourth resistor sections R21 to R24. The first to fourth resistor sections R11 to R14, the first to fourth reference directions M11 to M14, and the first to fourth magnetization directions m11 to m14 in the description on the first to fourth directions of the first to fourth resistor sections R11 to R14 are replaced with the first to fourth resistor sections R21 to R24, the first to fourth reference directions M21 to M24, and the first to fourth magnetization directions m21 to m24, respectively. With this, the description on the first to fourth directions of the first to fourth resistor sections R21 to R24 is given.

Next, with reference to FIGS. 4 and 5, description is made on examples of the first to fourth magnetization directions m11 to m14, the first to fourth magnetization directions m21 to m24, the first to fourth reference directions M11 to M14, and the first to fourth reference directions M21 to M24. FIG. 5 shows the direction of the first magnetization direction m11. The first magnetization direction m11 is a direction obtained by rotating the reference direction DR counterclockwise by 151 degrees. In other words, the angle formed between the reference direction DR and the first magnetization direction m11 is 151 degrees. Note that, similarly to the rotating magnetic field angle θ, the angle is expressed as a positive value as viewed counterclockwise from the reference direction DR and a negative value as viewed clockwise from the reference direction DR. In the following description, the first magnetization direction m11 is expressed as the angle formed between the reference direction DR and the first magnetization direction m11. The magnetization directions other than the first magnetization direction m11 and the reference direction are also expressed similarly to the first magnetization direction m11.

As described above, the first reference direction M11 matches with the first magnetization direction m11. As shown in FIG. 4, the first reference direction M11 is 151 degrees. As shown in FIG. 4, the second reference direction M12 is 290 degrees, the third reference direction M13 is 154 degrees, and the fourth reference direction M14 is 184 degrees. Although omitted in illustration, the second magnetization direction m12 is 290 degrees, the third magnetization direction m13 is 154 degrees, and the fourth magnetization direction m14 is 184 degrees.

As shown in FIG. 4, the first reference direction M21 is 97 degrees, the second reference direction M22 is 252 degrees, the third reference direction M23 is 100 degrees, and the fourth reference direction M24 is 280 degrees. Although omitted in illustration, the first magnetization direction m21 is 97 degrees, the second magnetization direction m22 is 252 degrees, the third magnetization direction m23 is 100 degrees, and the fourth magnetization direction m24 is 280 degrees.

Note that the magnetization direction and the reference direction may be deviated slightly from the above-mentioned directions in view of accuracy of producing the MR element 50 or the like.

Next, with reference to FIG. 4, a configuration of the logic signal generation circuit 20 is described. The logic signal generation circuit 20 is configured to obtain the first detection signal S1 and the second detection signal S2, generate and output a first logic signal Su by using the first detection signal S1, generate and output a second logic signal Sv having a phase different from that of the first logic signal Su by using the second detection signal S2, and generate and output a third logic signal Sw having a phase different from those of the first and second logic signals Su and Sv by using the first and second detection signals S1 and S2.

The logic signal generation circuit 20 can be implemented by an application-specific integrated circuit (ASIC) or a plurality of comparators, for example. Note that the logic signal generation circuit 20 that can be configured as a chip, like the logic signal generation circuit 20 implemented by an ASIC, is also referred to as a “logic signal generator” in particular.

The logic signal generation circuit 20 includes a power supply terminal 20 a, a ground terminal 20b, a first input terminal 20c, a second input terminal 20d, a first output terminal 20e, a second output terminal 20f, a third output terminal 20g, a first comparator 21, a second comparator 22, a third comparator 23, and two resistors 24 and 25. The first comparator 21 includes a first input end 21a, a second input end 21b, and an output end 21c. The second comparator 22 includes a first input end 22a, a second input end 22b, and an output end 22c. The third comparator 23 includes a first input end 23a, a second input end 23b, and an output end 23c.

An end of the resistor 24 is connected to the power supply terminal 20a. An end of the resistor 25 is connected to the other end of the resistor 24. The other end of the resistor 25 is connected to the ground terminal 20b. A voltage of a specific magnitude is applied to the power supply terminal 20a. The ground terminal 20b is grounded.

The first input end 21 a of the first comparator 21 and the first input end 23 a of the third comparator 23 are connected to the first input terminal 20c. The first input end 22a of the second comparator 22 and the second input end 23b of the third comparator 23 are connected to the second input terminal 20d. The second input end 21b of the first comparator 21 and the second input end 22b of the second comparator 22 are connected to the connection point of the resistor 24 and the resistor 25.

The first output terminal 10c of the first detection circuit 10 is connected to the first input terminal 20c of the logic signal generation circuit 20. The first output terminal 10c is connected to the first input end 21a of the first comparator 21 and the first input end 23a of the third comparator 23 via the first input terminal 20c. The second output terminal 10d of the detection circuit 10 is connected to the second input terminal 20d of the logic signal generation circuit 20. The second output terminal 10d is connected to the first input end 22a of the second comparator 22 and the second input end 23b of the third comparator 23 via the second input terminal 20d.

The output end 21c of the first comparator 21 is connected to the first output terminal 20e. The first output terminal 20e outputs the signal output from the output end 21c of the first comparator 21 as the first logic signal Su.

The output end 22c of the second comparator 22 is connected to the second output terminal 20f. The second output terminal 20f outputs the signal output from the output end 22c of the second comparator 22 as the second logic signal Sv.

The output end 23c of the third comparator 23 is connected to the third output terminal 20g. The third output terminal 20g outputs the signal output from the output end 23c of the third comparator 23 as the third logic signal Sw.

Next, the first and second detection signals S1 and S2, and the first to third logic signals Su, Sv, and Sw are described. First, the first and second detection signals S1 and S2 are described. The first differential amplifier 13 generates a signal corresponding to a potential difference between the first and second output ports E11 and E12 as the first detection signal S1. The second differential amplifier 14 generates a signal corresponding to a potential difference between the first and second output ports E21 and E22 as the second detection signal S2.

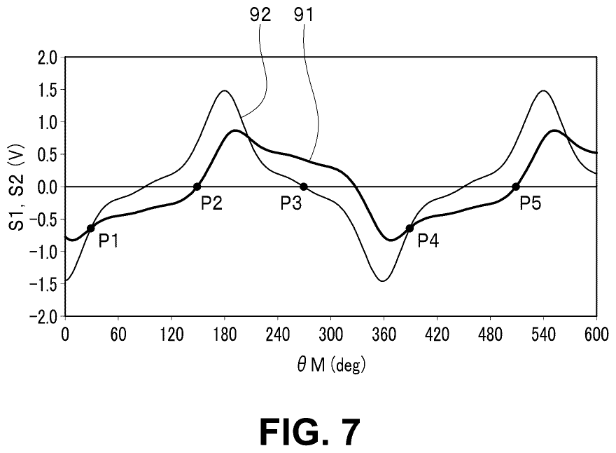

FIG. 7 is a waveform chart showing a waveform of each of the first and second detection signals S1 and S2. In FIG. 7, the horizontal axis indicates the rotation angle θM of the motor 70, and the vertical axis indicates the magnitude of each of the first and second detection signals S1 and S2. In FIG. 7, the reference symbol 91 represents the first detection signal S1, and the reference symbol 92 represents the second detection signal S2. FIG. 7 shows a range in which the rotation angle θM is 0 degrees or more and 600 degrees or less. Note that, in the example embodiment, the value of the rotation angle θM is the same or substantially the same as the value of the rotating magnetic field angle θ.

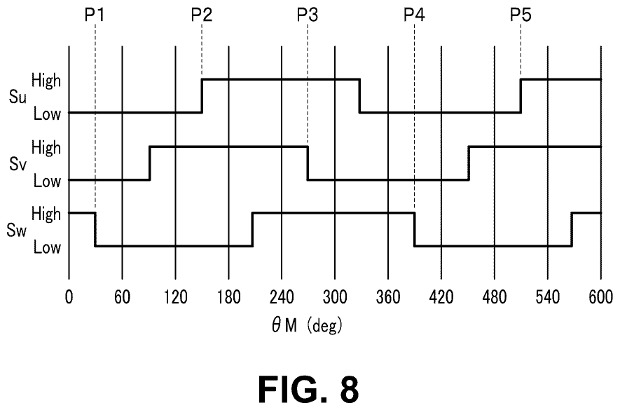

Next, with reference to FIGS. 7 and 8, the first to third logic signals Su, Sv, and Sw are described. FIG. 8 is a timing chart showing the first to third logic signals Su, Sv, and Sw.

First, the first logic signal Su is described. The first detection signal S1 is input to the first input end 21a of the first comparator 21. A reference voltage with a magnitude corresponding to a value of 0 on the vertical axis of FIG. 7 is input to the second input end 21b of the first comparator 21. The first comparator 21 compares the value of the first detection signal S1 with the value of the reference voltage, and outputs the first logic signal Su. Within the range of the rotation angle θM shown in FIG. 7, the value of the first detection signal S1 is more than the value of the reference voltage (0 on the vertical axis of FIG. 7) when the rotation angle θM corresponds to a first case where 149.6 degrees<θM<327.8 degrees or 509.6 degrees<θM≤600 degrees is satisfied, and is less than the value of the reference voltage when the rotation angle θM corresponds to a second case where 0 degrees≤θM<149.6 degrees or 327.8 degrees<θM <509.6 degrees is satisfied. Therefore, within the range described above, the first comparator 21 outputs a High-level signal when the rotation angle θM corresponds to the first case, and outputs a Low-level signal when the rotation angle θM corresponds to the second case.

Next, the second logic signal Sv is described. The second detection signal S2 is input to the first input end 22a of the second comparator 22. The reference voltage with the magnitude corresponding to the value of 0 on the vertical axis of FIG. 7 is input to the second input end 22b of the second comparator 22. The second comparator 22 compares the value of the second detection signal S2 with the value of the reference voltage, and outputs the second logic signal Sv. Within the range of the rotation angle θM shown in FIG. 7, the value of the second detection signal S2 is more than the value of the reference voltage when the rotation angle θM satisfies a third case where 91 degrees<θM<269.1 degrees or 451 degrees<θM≤600 degrees is satisfied, and is less than the value of the reference voltage when the rotation angle θM satisfies a fourth case where 0 degrees≤θM<91 degrees or 269.1 degrees<θM<451 degrees is satisfied. Therefore, within the range described above, the second comparator 22 outputs the High-level signal when the rotation angle θM corresponds to the third case, and outputs the Low-level signal when the rotation angle θM corresponds to the fourth case.

Next, the third logic signal Sw is described. The first detection signal S1 is input to the first input end 23a of the third comparator 23. The second detection signal S2 is input to the second input end 23b of the third comparator 23. The third comparator 23 compares the value of the first detection signal S1 with the value of the second detection signal S2, and outputs the third logic signal Sw. Within the range of the rotation angle θM shown in FIG. 7, the value of the first detection signal S1 is more than the second detection signal S2 when the rotation angle θM corresponds to the fifth case where 0 degrees≤θM<29.5 degrees, 207 degrees<θM<389.5 degrees, or 567 degrees<θM≤600 degrees is satisfied, and is less than the value of the second detection signal S2 when the rotation angle θM corresponds to a sixth case where 29.5 degrees<θM<207 degrees or 389.5 degrees<θM<567 degrees is satisfied. Therefore, within the range described above, the third comparator 23 outputs the High-level signal when the rotation angle θM corresponds to the fifth case, and outputs the Low-level signal when the rotation angle θM corresponds to the sixth case.

In the example embodiment, the control circuit 121 detects the rotation angle θM by using the first to third logic signals Su, Sv, and Sw. In particular, in the example embodiment, the first and second bridge circuits 11 and 12 may be configured so that a temporal period corresponding to one rotation in the direction of the rotation angle θM is divided into three or more temporal sub-periods, based on the first detection signal S1 and the second detection signal S2. The control circuit 121 can detect the three or more temporal sub-periods by using the first to third logic signals Su, Sv, and Sw. With this, the control circuit 121 can detect the rotation angle θM. For example, when the temporal period corresponding to one rotation in the direction of the rotation angle θM is divided into three sub-periods, the control circuit 121 may be able to detect that the direction of the rotation angle θM makes approximately one-third of a rotation, in other words, the rotation angle θM changes by approximately 120 degrees. When the temporal period corresponding to one rotation in the direction of the rotation angle θM is divided into six sub-periods, the control circuit 121 can detect that the direction of the rotation angle θM makes approximately one-sixth of a rotation, in other words, the rotation angle θM changes by approximately 60 degrees.

For example, the control circuit 121 can detect the three or more temporal sub-periods by detecting the timing at which each of the first to third logic signals Su, Sv, and Sw is switched from one of the High-level signal and the Low-level signal to the other. In FIG. 8, the symbol P1 represents a timing at which the third logic signal Sw is switched from the High-level signal to the Low-level signal. The symbol P2 represents a timing at which the first logic signal Su is switched from the Low-level signal to the High-level signal. The symbol P3 represents a timing at which the second logic signal Sv is switched from the High-level signal to the Low-level signal. The symbol P4 represents a timing at which the third logic signal Sw is switched from the High-level signal to the Low-level signal. The symbol P5 represents a timing at which the first logic signal Su is switched from the Low-level signal to the High-level signal.

FIG. 7 shows five points corresponding to the timings P1 to P5 shown in FIG. 8. The point corresponding to the timing P1 is a point at which the magnitude of the first detection signal S1 and the magnitude of the second detection signal S2 are equal to each other, and a point at which the rotation angle θM is 29.5 degrees. The point corresponding to the timing P2 is a point at which the magnitude of the first detection signal S1 is 0 and a point at which the rotation angle θM is 149.6 degrees. The point corresponding to the timing P3 is a point at which the magnitude of the second detection signal S2 is 0 and a point at which the rotation angle θM is 269.1 degrees. The point corresponding to the timing P4 is a point at which the magnitude of the first detection signal S1 and the magnitude of the second detection signal S2 are equal to each other, and a point at which the rotation angle θM is 389.5 degrees. The point corresponding to the timing P5 is a point at which the magnitude of the first detection signal S1 is 0 and a point at which the rotation angle θM is 509.6 degrees.

In a temporal sub-period from the timing P1 to the timing P2, the rotation angle θM changes by 120.1 degrees. In a temporal sub-period from the timing P2 to the timing P3, the rotation angle θM changes by 119.5 degrees. In a temporal sub-period from the timing P3 to the timing P4, the rotation angle θM changes by 120.4 degrees. In a temporal sub-period from the timing P4 to the timing P5, the rotation angle θM changes by 120.1 degrees. Therefore, the control circuit 121 can substantially detect the temporal sub-periods by detecting the timings P1 to P5. With this, the control circuit 121 can detect that the rotation angle θM changes by approximately 120 degrees.

For example, a timing for detecting the rotation angle θM (hereinafter, referred to as a detection timing) is defined in the following manner. When a timing at which the first logic signal Su is switched from one of the High-level signal and the Low-level signal to the other is defined as a first detection timing, a subsequent timing at which the second logic signal Sv is switched from one of the High-level signal and the Low-level signal to the other is defined as a second detection timing, a subsequent timing at which the third logic signal Sw is switched from one of the High-level signal and the Low-level signal to the other is defined as a third detection timing, and a subsequent timing at which the first logic signal Su is switched from one of the High-level signal and the Low-level signal to the other is defined as a fourth detection timing.

Alternatively, the detection timing can be defined in the following manner. When the timing at which any one of the first to third logic signals Su, Sv, and Sw is switched from one of the High-level signal and the Low-level signal to the other is detected for a plurality of times, a third timing counted from the first detection timing is defined as the second detection timing, a fifth timing counted from the first detection timing is defined as the third detection timing, and a seventh timing counted from the first detection timing is defined as the fourth detection timing.

Next, a method for manufacturing the magnetic sensor 1 according to the example embodiment is described. The method for manufacturing the magnetic sensor 1 includes a step of forming the first bridge circuit 11 and a step of forming the second bridge circuit 12. The step of forming the first bridge circuit 11 includes an element formation step of forming the plurality of MR elements 50 and a step of forming the plurality of wiring lines so as to form the first to fourth resistor sections R11 to R14. The step of forming the second bridge circuit 12 includes an element formation step of forming the plurality of MR elements 50 and a step of forming a plurality of wiring lines so as to form the first to fourth resistor sections R21 to R24.

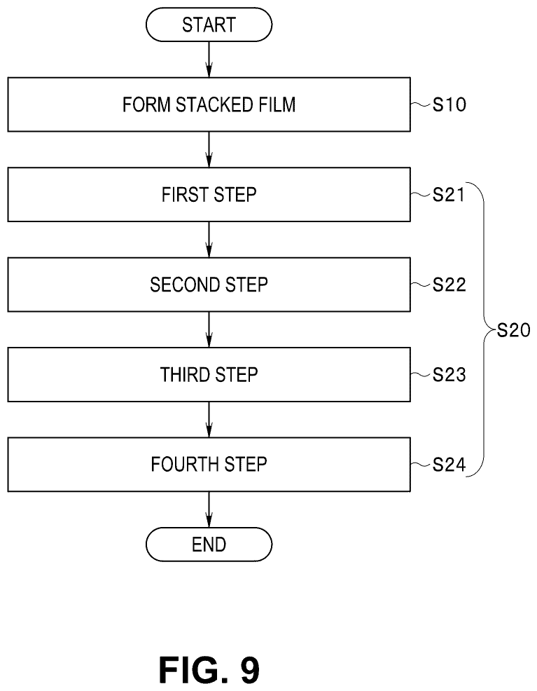

The element formation step is described below while focusing on the first bridge circuit 11 as an example. FIG. 9 is a flowchart showing the element formation step for the first bridge circuit 11. In the element formation step, first, a stacked film including a plurality of first magnetic sections that later serve as the plurality of magnetization pinned layers 52 and a plurality of second magnetic sections that later serve as the plurality of free layers 54 is formed (Step S10). The stacked film further includes a nonmagnetic layer that later serves as the plurality of gap layers 53 and an antiferromagnetic layer that later serves as the plurality of antiferromagnetic layers 51. Subsequently, a fixation step of fixing a magnetization direction of each of the plurality of first magnetic sections by using laser light and an external magnetic field having a specific direction is executed (Step S20). The fixation step includes the first step (Step S21), the second step (Step S22), the third step (Step S23), and the fourth step (Step S24).

In the first step (Step S21), magnetization directions of first specific magnetic sections, among the plurality of first magnetic sections, which later serve as the plurality of magnetization pinned layers 52 of the plurality of first MR elements 50A1 constituting the first resistor section R11 are fixed. Specifically, while applying the external magnetic field having the same direction as the first magnetization direction m11 shown in FIG. 5 (the same direction as the first reference direction M11 shown in FIG. 4), a part of the stacked film, which corresponds to the first specific magnetic section, is irradiated with the laser light. When the stacked film includes the antiferromagnetic layer, irradiation with the laser light is performed so that the temperature of the stacked film irradiated with the laser light is equal to or higher than the blocking temperature of the antiferromagnetic layer. The temperature of the stacked film may be adjusted by intensity of the laser light or a pulse width, for example. After irradiation with the laser light, the temperature of the stacked film is lower than the blocking temperature. With this, the magnetization directions of the first specific magnetic sections are fixed to the first magnetization direction m11.

In the second step (Step S22), similarly to the first step, magnetization directions of second specific magnetic sections, among the plurality of first magnetic sections, which later serve as the plurality of magnetization pinned layers 52 of the plurality of second MR elements 50B1 constituting the second resistor section R12 are fixed. Specifically, while applying the external magnetic field having the same direction as the second magnetization direction m12 (the same direction as the second reference direction M12 shown in FIG. 4), a part of the stacked film, which corresponds to the second specific magnetic section, is irradiated with the laser light. After the second step, the magnetization directions of the second specific magnetic sections are fixed to the second magnetization direction m12.

In the third step (Step S23), similarly to the first step, magnetization directions of third specific magnetic sections, among the plurality of first magnetic sections, which later serve as the plurality of magnetization pinned layers 52 of the plurality of third MR elements 50C1 constituting the third resistor section R13 are fixed. Specifically, while applying the external magnetic field having the same direction as the third magnetization direction m13 (the same direction as the third reference direction M13 shown in FIG. 4), a part of the stacked film, which corresponds to the third specific magnetic section, is irradiated with the laser light. After the third step, the magnetization directions of the third specific magnetic sections are fixed to the third magnetization direction m13.

In the fourth step (Step S24), similarly to the first step, magnetization directions of fourth specific magnetic sections, among the plurality of first magnetic sections, which later serve as the plurality of magnetization pinned layers 52 of the plurality of fourth MR elements 50D1 constituting the fourth resistor section R14 are fixed. Specifically, while applying the external magnetic field having the same direction as the fourth magnetization direction m14 (the same direction as the fourth reference direction M14 shown in FIG. 4), a part of the stacked film, which corresponds to the fourth specific magnetic section, is irradiated with the laser light. After the fourth step, the magnetization directions of the fourth specific magnetic sections are fixed to the fourth magnetization direction m14.

Note that the order of the first to fourth steps is not limited to the example shown in FIG. 9, and may be freely selected. The direction of the external magnetic field may be set by changing a direction of the external magnetic field itself or by changing a posture of the stacked film.

The element formation step further includes a step of performing patterning so as to turn the stacked film into the plurality of MR elements 50. The step may be executed after the fixation step, or may be executed between the step of forming the stacked film and the fixation step.

The element formation step is described above while focusing on the first bridge circuit 11 as an example. The element formation step in the step of forming the second bridge circuit 12 is basically similar to the element formation step in the step of forming the first bridge circuit 11. The first to fourth resistor sections R11 to R14, the first to fourth MR elements 50A1, 50B1, 50C1, and 50D1, the first to fourth magnetization directions m11 to m14, and the first to fourth reference directions M11 to M14 in the description on the element formation step in the step of forming the first bridge circuit 11 are replaced with the first to fourth resistor sections R21 to R24, the first to fourth MR elements 50A2, 50B2, 50C2, and 50D2, the first to fourth magnetization directions m21 to m24, and the first to fourth reference directions M21 to M24, respectively. With this, the description on the element formation step in the step of forming the second bridge circuit 12 is given.

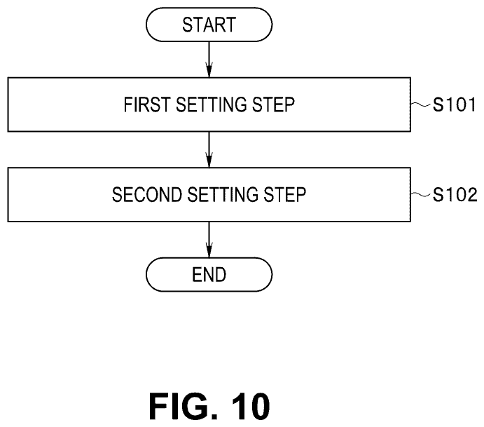

Next, a method for designing the magnetic sensor 1 according to the example embodiment is described. The method for designing the magnetic sensor 1 is a method for setting the magnetization direction of the magnetization pinned layer 52 so that the magnetic sensor 1 can be used for rotation control of the motor 70. FIG. 10 is a flowchart showing the method for designing the magnetic sensor 1. The method for designing the magnetic sensor 1 includes a first setting step (Step S101) and a second setting step (Step S102).

In the first setting step (S101), the magnetization directions of the plurality of magnetization pinned layers 52 of the plurality of first MR elements 50A1 constituting the first resistor section R11, the magnetization directions of the plurality of magnetization pinned layers 52 of the plurality of second MR elements 50B1 constituting the second resistor section R12, the magnetization directions of the plurality of magnetization pinned layers 52 of the plurality of third MR elements 50C1 constituting the third resistor section R13, and the magnetization directions of the plurality of magnetization pinned layers 52 of the plurality of fourth MR elements 50D1 constituting the fourth resistor section R14 are set so that the first bridge circuit 11 generates the first detection signal S1. In particular, in the example embodiment, the first setting step is executed so that the direction obtained by averaging the magnetization directions of the plurality of magnetization pinned layers 52 in the first MR elements 50A1 is defined as the first magnetization direction m11, the direction obtained by averaging the magnetization directions of the plurality of magnetization pinned layers 52 in the second MR elements 50B1 is defined as the second magnetization direction m12, the direction obtained by averaging the magnetization directions of the plurality of magnetization pinned layers 52 in the third MR elements 50C1 is defined as the third magnetization direction m13, and the direction obtained by averaging the magnetization directions of the plurality of magnetization pinned layers 52 in the fourth MR elements 50D1 is defined as the fourth magnetization direction m14. 117 In the first setting step, the magnetization directions of the plurality of magnetization pinned layers 52 of the plurality of first MR elements 50A2 constituting the first resistor section R21, the magnetization directions of the plurality of magnetization pinned layers 52 of the plurality of second MR elements 50B2 constituting the second resistor section R22, the magnetization directions of the plurality of magnetization pinned layers 52 of the plurality of third MR elements 50C2 constituting the third resistor section R23, and the magnetization directions of the plurality of magnetization pinned layers 52 of the plurality of fourth MR elements 50D2 constituting the fourth resistor section R24 are further set so that the second bridge circuit 12 generates the second detection signal S2. In particular, in the example embodiment, the first setting step is executed so that the direction obtained by averaging the magnetization directions of the plurality of magnetization pinned layers 52 in the first MR elements 50A2 is defined as the first magnetization direction m21, the direction obtained by averaging the magnetization directions of the plurality of magnetization pinned layers 52 in the second MR elements 50B2 is defined as the second magnetization direction m22, the direction obtained by averaging the magnetization directions of the plurality of magnetization pinned layers 52 in the third MR elements 50C2 is defined as the third magnetization direction m23, and the direction obtained by averaging the magnetization directions of the plurality of magnetization pinned layers 52 in the fourth MR elements 50D2 is defined as the fourth magnetization direction m24. 118 In the second setting step (Step S102), the magnetization directions of the plurality of magnetization pinned layers 52 described above are set so that the time period corresponding to one rotation in the direction of the rotating magnetic field MF (rotation of the rotation angle θM) is divided into the three or more temporal sub-periods, based on the first detection signal S1 and the second detection signal S2. In particular, in the example embodiment, in the second setting step, the direction of each of the magnetization directions m11 to m14 and m21 to m24 is set.

When the direction of the rotating magnetic field MF rotates with a specific period, each of the first and second detection signals S1 and S2 includes an ideal component that periodically varies so as to form an ideal sinusoidal curve and a plurality of harmonic components corresponding to higher-order harmonics of the respective ideal components. When the first to fourth magnetization directions m11 to m14 change, the initial phases of the plurality of harmonic components change. With this, the waveform of the first detection signal S1 changes. When the first to fourth magnetization directions m21 to m24 change, the initial phases of the plurality of harmonic components change. With this, the waveform of the second detection signal S2 changes. In the second setting step, the magnetization directions of the plurality of magnetization pinned layers 52 are set so as to obtain the three or more temporal sub-periods, by using the influence of the first to fourth magnetization directions m11 to m14 over the waveform of the first detection signal S1 and the influence of the first to fourth magnetization directions m21 to m24 over the waveform of the second detection signal S2.

In particular, in the example embodiment, the magnetization directions of the plurality of magnetization pinned layers 52 may be set so that the above-mentioned sub-period corresponds to a change in the direction of the rotating magnetic field MF within 120 degrees ±α. In this manner, in the magnetic sensor 1, the first and second bridge circuits 11 and 12 for generating the first and second detection signals S1 and S2 that can be used for rotation control of the motor 70 are configured. α is preferably 10 degrees, for example.

Next, the operation and effects of the magnetic sensor 1 according to the example embodiment are described. In the example embodiment, the three resistor sections of the first to fourth resistor sections R11 to R14 of the first bridge circuit 11 are configured so that the three magnetization directions corresponding to the three resistor sections intersect with one another at angles other than 0 degrees and 180 degrees. In particular, in the example embodiment, the first to fourth resistor sections R11 to R14 are configured so that the first to fourth magnetization directions m11 to m14 intersect with one another at angles other than 0 degrees and 180 degrees. In the example embodiment, the three resistor sections of the first to fourth resistor sections R21 to R24 of the second bridge circuit 12 are configured so that the three magnetization directions corresponding to the three resistor sections intersect with one another at angles other than 0 degrees and 180 degrees. In particular, in the example embodiment, the first to fourth resistor sections R21 to R24 are configured so that the first to fourth magnetization directions m21 to m24 intersect with one another at angles other than 0 degrees and 180 degrees. With this, according to the example embodiment, the three or more temporal sub-periods can be detected based on the first detection signal S1 generated by the first bridge circuit 11 and the second detection signal S2 generated by the second bridge circuit 12, and the rotation angle θM can be detected. As a result, according to the example embodiment, the first and second detection signals S1 and S2 can be used for rotation control of the motor 70.

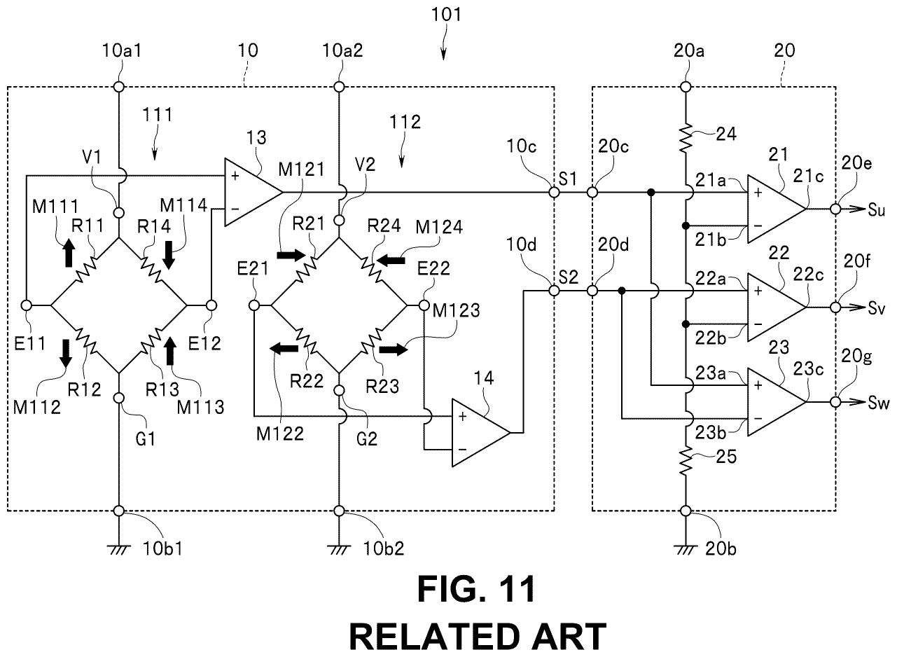

The above-mentioned effects are described below in detail while comparing with a magnetic sensor in a comparative example. First, with reference to FIG. 11, a configuration of a magnetic sensor 101 in the comparative example is described. FIG. 11 is a circuit diagram showing a circuit configuration of the magnetic sensor 101 in the comparative example. The magnetic sensor 101 in the comparative example includes a first bridge circuit 111 and a second bridge circuit 112 in place of the first and second bridge circuits 11 and 12 in the example embodiment. Other configurations of the magnetic sensor 101 in the comparative example are similar to the configurations of the magnetic sensor 1 according to the example embodiment.

The configuration of the first bridge circuit 111 is basically the same as the configuration of the first bridge circuit 11 in the example embodiment. However, in the first bridge circuit 111, the sensitivity direction of each of the first to fourth resistor sections R11 to R14 is different from the sensitivity direction of each of the first to fourth resistor sections R11 to R14 in the example embodiment. In other words, in the comparative example, the first resistor section R11 has sensitivity in a first direction parallel to a first reference direction M111, the second resistor section R12 has sensitivity in a second direction parallel to a second reference direction M112, the third resistor section R13 has sensitivity in a third direction parallel to a third reference direction M113, and the fourth resistor section R14 has sensitivity in a fourth direction parallel to a fourth reference direction M114. As shown in FIG. 11, the first reference direction M111 and the third reference direction M113 are 90 degrees, and the second reference direction M112 and the fourth reference direction M114 are 270 degrees.

In the comparative example, the first magnetization direction being a direction obtained by averaging the magnetization directions of the plurality of magnetization pinned layers 52 included in the plurality of first MR elements 50A1 constituting the first resistor section R11 is the same direction as the first reference direction M111. The second magnetization direction being a direction obtained by averaging the magnetization directions of the plurality of magnetization pinned layers 52 included in the plurality of second MR elements 50B1 constituting the second resistor section R12 is the same direction as the second reference direction M112. The third magnetization direction being a direction obtained by averaging the magnetization directions of the plurality of magnetization pinned layers 52 included in the plurality of third MR elements 50C1 constituting the third resistor section R13 is the same direction as the third reference direction M113. The fourth magnetization direction being a direction obtained by averaging the magnetization directions of the plurality of magnetization pinned layers 52 included in the plurality of fourth MR elements 50D1 constituting the fourth resistor section R14 is the same direction as the fourth reference direction M114.

The first magnetization direction and the third magnetization direction are the same direction, the second magnetization direction and the fourth magnetization direction are the same direction, the first magnetization direction and the second magnetization direction are directions different from each other by 180 degrees, and the third magnetization direction and the fourth magnetization direction are directions different from each other by 180 degrees. Therefore, in the comparative example, the first to fourth resistor sections R11 to R14 are not configured so that the first to fourth magnetization directions intersect with one another.

The configuration of the second bridge circuit 112 is basically the same as the configuration of the second bridge circuit 12 in the example embodiment. However, in the second bridge circuit 112, the sensitivity direction of each of the first to fourth resistor sections R21 to R24 is different from the sensitivity direction of each of the first to fourth resistor sections R21 to R24 in the example embodiment. In other words, in the comparative example, the first resistor section R21 has sensitivity in a first direction parallel to a first reference direction M121, the second resistor section R22 has sensitivity in a second direction parallel to a second reference direction M122, the third resistor section R23 has sensitivity in a third direction parallel to a third reference direction M123, and the fourth resistor section R24 has sensitivity in a fourth direction parallel to a fourth reference direction M124. As shown in FIG. 11, the first reference direction M121 and the third reference direction M123 are 0 degrees, and the second reference direction M122 and the fourth reference direction M124 are 180 degrees.

In the comparative example, the first magnetization direction being a direction obtained by averaging the magnetization directions of the plurality of magnetization pinned layers 52 included in the plurality of first MR elements 50A2 constituting the first resistor section R21 is the same direction as the first reference direction M121. The second magnetization direction being a direction obtained by averaging the magnetization directions of the plurality of magnetization pinned layers 52 included in the plurality of second MR elements 50B2 constituting the second resistor section R22 is the same direction as the second reference direction M122. The third magnetization direction being a direction obtained by averaging the magnetization directions of the plurality of magnetization pinned layers 52 included in the plurality of third MR elements 50C2 constituting the third resistor section R23 is the same direction as the third reference direction M113. The fourth magnetization direction being a direction obtained by averaging the magnetization directions of the plurality of magnetization pinned layers 52 included in the plurality of fourth MR elements 50D2 constituting the fourth resistor section R14 is the same direction as the fourth reference direction M114.

The first magnetization direction and the third magnetization direction are the same direction, the second magnetization direction and the fourth magnetization direction are the same direction, the first magnetization direction and the second magnetization direction are directions different from each other by 180 degrees, and the third magnetization direction and the fourth magnetization direction are directions different from each other by 180 degrees. Therefore, in the comparative example, the first to fourth resistor sections R21 to R24 are not configured so that the first to fourth magnetization directions intersect with each other.

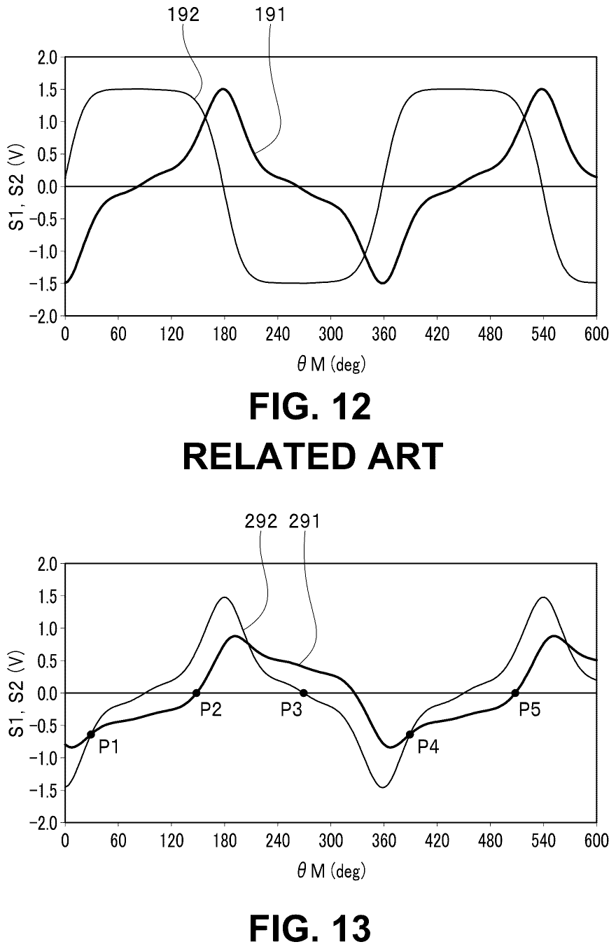

Next, with reference to FIG. 12, the first and second detection signals S1 and S2 in the comparative example are described. FIG. 12 is a waveform chart showing a waveform of each of the first and second detection signals S1 and S2 in the comparative example. In FIG. 12, the horizontal axis indicates the rotation angle θM of the motor 70, and the vertical axis indicates the magnitude of each of the first and second detection signals S1 and S2 in the comparative example. In FIG. 12, the reference symbol 191 represents the first detection signal S1 in the comparative example, and the reference symbol 192 represents the second detection signal S2 in the comparative example. Further, FIG. 12 shows a range in which the rotation angle θM is 0 degrees or more and 600 degrees or less.

Within the range of the rotation angle θM shown in FIG. 12, the value of the first detection signal S1 in the comparative example is more than the value of the reference voltage (0 on the vertical axis of FIG. 12) when the rotation angle θM satisfies 83 degrees<θM<262.7 degrees or 443 degrees<θM≤600 degrees, and is less than the value of the reference voltage when the rotation angle θM satisfies 0 degrees≤θM<83 degrees or 262.7 degrees<θM<443 degrees.

Within the range of the rotation angle θM shown in FIG. 12, the value of the second detection signal S2 in the comparative example is more than the value of the reference voltage when the rotation angle θM satisfies 0 degrees≤θM<178.8 degrees or 358.8 degrees<θM<538.8 degrees, and is less than the value of the reference voltage when the rotation angle θM satisfies 178.8 degrees<θM<358.8 degrees or 538.8 degrees<θM≤600 degrees.

Within the range of the rotation angle θM shown in FIG. 12, the value of the first detection signal S1 in the comparative example is more than the second detection signal S2 when the rotation angle θM satisfies 158.7 degrees<θM<338.6 degrees or 518.7 degrees<θM≤600 degrees, and is less than the value of the second detection signal S2 when the rotation angle θM satisfies 0 degrees≤θM<158.7 degrees or 338.6 degrees<θM<518.7 degrees.

Similarly to the example embodiment, the logic signal generation circuit 20 of the comparative example generates the first to third logic signals Su, Sv, and Sw by using the first and second detection signals S1 and S2 of the comparative example. However, in the comparative example, the first to third logic signals Su, Sv, and Sw cannot be used for rotation control of the motor 70. For example, when the timing at which any one of the first to third logic signals Su, Sv, and Sw is switched from one of the High-level signal and the Low-level signal to the other is detected for a plurality of times, a third timing counted from the first detection timing is defined as the second detection timing, a fifth timing counted from the first detection timing is defined as the third detection timing, and a seventh timing counted from the first detection timing is defined as the fourth detection timing. When the first detection timing is a timing at which the rotation angle θM is 0 degrees, the second detection timing is a timing at which the rotation angle θM is 158.7 degrees, the third detection timing is a timing at which the rotation angle θM is 262.7 degrees, and the fourth detection timing is a timing at which the rotation angle θM is 358.8 degrees.

In a temporal sub-period from the first detection timing to the second detection timing, the rotation angle θM changes by 158.7 degrees. In a temporal sub-period from the second detection timing to the third detection timing, the rotation angle θM changes by 104 degrees. In a temporal sub-period from the third detection timing to the fourth detection timing, the rotation angle θM changes by 96.1 degrees. In order to use the first to third logic signals Su, Sv, and Sw for rotation control of the motor 70, the change amount of the rotation angle θM is required to be the same or substantially the same among the plurality of temporal sub-periods detected by the control circuit 121. However, in the comparative example, the change amount of the rotation angle θM differs for each temporal sub-period.

In contrast, in the example embodiment, as described above, in any one of the plurality of temporal sub-periods detected by the control circuit 121, the change amount of the rotation angle θM is approximately 120 degrees. With this, according to the example embodiment, the first to third logic signals Su, Sv, and Sw, in other words, the first and second detection signals S1 and S2 can be used for rotation control of the motor 70.

### Modification Examples

Next, first to third modification examples of the magnetic sensor 1 according to the example embodiment are described. First, the first modification example of the magnetic sensor 1 is described. In the first modification example, the configuration of the third resistor section R13 of the first bridge circuit 11 is different from the example shown in FIG. 4. As described above, the third resistor section R13 has sensitivity in the third direction parallel to the third reference direction M13. In the first modification example, the third reference direction M13 is 151 degrees, and is the same direction as the first reference direction M11. Although omitted in illustration, the third magnetization direction m13 being a direction obtained by averaging the magnetization directions of the plurality of magnetization pinned layers 52 included in the plurality of third MR elements 50C1 constituting the third resistor section R13 is also 151 degrees. Therefore, the third magnetization direction m13 is the same direction as the first magnetization direction m11 being a direction obtained by averaging the magnetization directions of the plurality of magnetization pinned layers 52 included in the plurality of first MR elements 50A1 constituting the first resistor section R11.

FIG. 13 is a waveform chart showing a waveform of each of the first and second detection signals S1 and S2 in the first modification example. In FIG. 13, the horizontal axis indicates the rotation angle θM of the motor 70, and the vertical axis indicates the magnitude of each of the first and second detection signals S1 and S2. In FIG. 13, the reference symbol 291 represents the first detection signal S1, and the reference symbol 292 represents the second detection signal S2. Further, FIG. 13 shows a range in which the rotation angle θM is 0 degrees or more and 600 degrees or less.

Within the range of the rotation angle θM shown in FIG. 13, the value of the first detection signal S1 is more than the value of the reference voltage (0 on the vertical axis of FIG. 13) when the rotation angle θM corresponds to a first case where 148.8 degrees<θM<326.9 degrees or 508.8 degrees<θM≤600 degrees is satisfied, and is less than the value of the reference voltage when the rotation angle θM corresponds to the second case where 0 degrees≤θM<148.8 degrees or 326.9 degrees<θM<508.8 degrees is satisfied. Therefore, within the range described above, the first comparator 21 (see FIG. 4) outputs the High-level signal when the rotation angle θM corresponds to the first case, and outputs the Low-level signal when the rotation angle θM corresponds to the second case.

Within the range of the rotation angle θM shown in FIG. 13, the value of the second detection signal S2 is more than the value of the reference voltage when the rotation angle θM satisfies the third case where 91 degrees<θM<269.1 degrees or 451 degrees<θM≤600 degrees is satisfied, and is less than the value of the reference voltage when the rotation angle θM satisfies the fourth case where 0 degrees≤θM<91 degrees or 269.1 degrees<θM<451 degrees is satisfied. Therefore, within the range described above, the second comparator 22 (see FIG. 4) outputs the High-level signal when the rotation angle θM corresponds to the third case, and outputs the Low-level signal when the rotation angle θM corresponds to the fourth case.

Within the range of the rotation angle θM shown in FIG. 13, the value of the first detection signal S1 is more than the second detection signal S2 when the rotation angle θM corresponds to a fifth case where 0 degrees ≤θM <29.6 degrees, 207 degrees<θM<389.6 degrees, or 567 degrees <θM ≤600 degrees is satisfied, and is less than the value of the second detection signal S2 when the rotation angle θM corresponds to a sixth case where 29.6 degrees<θM<207 degrees or 389.6 degrees<θM<567 degrees is satisfied. Therefore, within the range described above, the third comparator 23 (see FIG. 4) outputs the High-level signal when the rotation angle θM corresponds to the fifth case, and outputs the Low-level signal when the rotation angle θM corresponds to the sixth case.

The point P1 shown in FIG. 13 is a point at which the magnitude of the first detection signal S1 and the magnitude of the second detection signal S2 are equal to each other, and a point at which the rotation angle θM is 29.6 degrees. The point P2 is a point at which the magnitude of the first detection signal S1 is 0 and a point at which the rotation angle θM is 148.8 degrees. The point P3 is a point at which the magnitude of the second detection signal S2 is 0 and a point at which the rotation angle θM is 269.1 degrees. The point P4 is a point at which the magnitude of the first detection signal S1 and the magnitude of the second detection signal S2 are equal to each other, and a point at which the rotation angle θM is 389.6 degrees. The point P5 is a point at which the magnitude of the first detection signal S1 is 0 and a point at which the rotation angle θM is 508.8 degrees.

In a temporal sub-period from the timing corresponding to the point P1 to the timing corresponding to the point P2, the rotation angle θM changes by 119.2 degrees. In a temporal sub-period from the timing corresponding to the point P2 to the timing corresponding to the point P3, the rotation angle θM changes by 120.3 degrees. In a temporal sub-period from the timing corresponding to the point P3 to the timing corresponding to the point P4, the rotation angle θM changes by 120.5 degrees. In a temporal sub-period from the timing corresponding to the point P4 to the timing corresponding to the point P5, the rotation angle θM changes by 119.2 degrees.

Next, the second modification example of the magnetic sensor 1 is described. In the second modification example, the configuration of the first resistor section R21 of the second bridge circuit 12 is different from the example shown in FIG. 4. As described above, the first resistor section R21 has sensitivity in the first direction parallel to the first reference direction M21. In the second modification example, the first reference direction M21 is 100 degrees, and is the same direction as the third reference direction M23. Although omitted in illustration, the first magnetization direction m21 being a direction obtained by averaging the magnetization directions of the plurality of magnetization pinned layers 52 included in the plurality of first MR elements 50A2 constituting the first resistor section R21 is also 100 degrees. Therefore, the first magnetization direction m21 is the same direction as the third magnetization direction m23 being a direction obtained by averaging the magnetization directions of the plurality of magnetization pinned layers 52 included in the plurality of third MR elements 50C2 constituting the third resistor section R23.

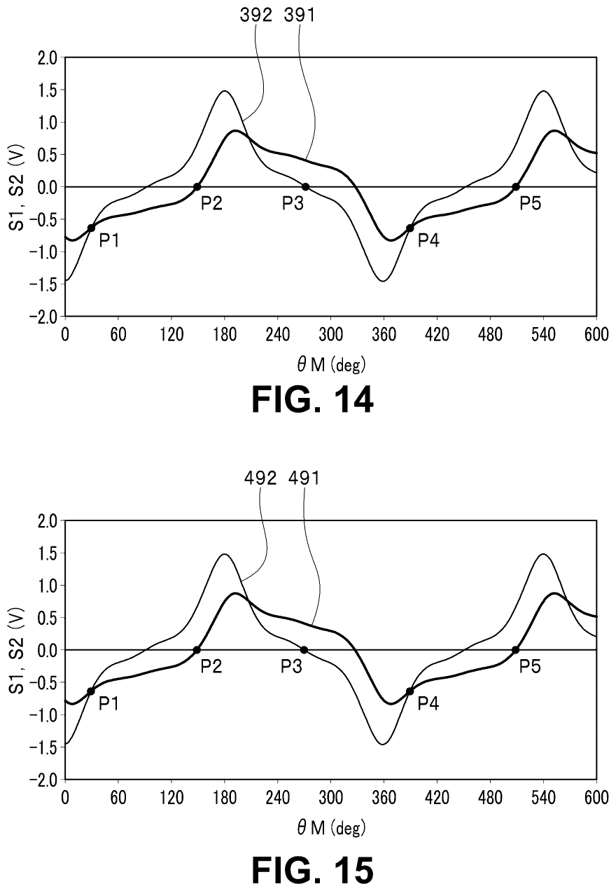

FIG. 14 is a waveform chart showing a waveform of each of the first and second detection signals S1 and S2 in the second modification example. In FIG. 14, the horizontal axis indicates the rotation angle θM of the motor 70, and the vertical axis indicates the magnitude of each of the first and second detection signals S1 and S2. In FIG. 14, the reference symbol 391 represents the first detection signal S1, and the reference symbol 392 represents the second detection signal S2. Further, FIG. 14 shows a range in which the rotation angle θM is 0 degrees or more and 600 degrees or less.

Within the range of the rotation angle θM shown in FIG. 14, the value of the first detection signal S1 is more than the value of the reference voltage (0 on the vertical axis of FIG. 14) when the rotation angle θM corresponds to the first case where 149.6 degrees<θM<327.8 degrees or 509.6 degrees<θM≤600 degrees is satisfied, and is less than the value of the reference voltage when the rotation angle θM corresponds to the second case where 0 degrees≤θM<149.6 degrees or 327.8 degrees<θM<509.6 degrees is satisfied. Therefore, within the range described above, the first comparator 21 (see FIG. 4) outputs the High-level signal when the rotation angle θM corresponds to the first case, and outputs the Low-level signal when the rotation angle θM corresponds to the second case.

Within the range of the rotation angle θM shown in FIG. 14, the value of the second detection signal S2 is more than the value of the reference voltage when the rotation angle θM corresponds to a third case where 93.3 degrees<θM<271.3 degrees or 453.3 degrees<θM≤600 degrees is satisfied, and is less than the value of the reference voltage when the rotation angle θM corresponds to a fourth case where 0 degrees≤θM<93.3 degrees or 271.3 degrees<θM<453.3 degrees is satisfied. Therefore, within the range described above, the second comparator 22 (see FIG. 4) outputs the High-level signal when the rotation angle θM corresponds to the third case, and outputs the Low-level signal when the rotation angle θM corresponds to the fourth case.

Within the range of the rotation angle θM shown in FIG. 14, the value of the first detection signal S1 is more than the second detection signal S2 when the rotation angle θM corresponds to a fifth case where 0 degrees≤θM<30.3 degrees, 207.9 degrees<θM<390.3 degrees, or 567.9 degrees<θM≤600 degrees is satisfied, and is less than the value of the second detection signal S2 when the rotation angle θM corresponds to a sixth case where 30.3 degrees<θM<207.9 degrees or 390.3 degrees<θM<567.9 degrees is satisfied. Therefore, within the range described above, the third comparator 23 (see FIG. 4) outputs the High-level signal when the rotation angle θM corresponds to the fifth case, and outputs the Low-level signal when the rotation angle θM corresponds to the sixth case.

The point P1 shown in FIG. 14 is a point at which the magnitude of the first detection signal S1 and the magnitude of the second detection signal S2 are equal to each other, and a point at which the rotation angle θM is 30.3 degrees. The point P2 is a point at which the magnitude of the first detection signal S1 is 0 and a point at which the rotation angle θM is 149.6 degrees. The point P3 is a point at which the magnitude of the second detection signal S2 is 0 and a point at which the rotation angle θM is 271.3 degrees. The point P4 is a point at which the magnitude of the first detection signal S1 and the magnitude of the second detection signal S2 are equal to each other, and a point at which the rotation angle θM is 390.3 degrees. The point P5 is a point at which the magnitude of the first detection signal S1 is 0 and a point at which the rotation angle θM is 509.6 degrees.

In a temporal sub-period from the timing corresponding to the point P1 to the timing corresponding to the point P2, the rotation angle θM changes by 119.3 degrees. In a temporal sub-period from the timing corresponding to the point P2 to the timing corresponding to the point P3, the rotation angle θM changes by 121.7 degrees. In a temporal sub-period from the timing corresponding to the point P3 to the timing corresponding to the point P4, the rotation angle θM changes by 119 degrees. In a temporal sub-period from the timing corresponding to the point P4 to the timing corresponding to the point P5, the rotation angle θM changes by 119.3 degrees.

Next, the third modification example of the magnetic sensor 1 is described. In the third modification example, the configuration of the third resistor section R13 of the first bridge circuit 11 is the same as the first modification example. In the third modification example, both the first reference direction M21 and the third reference direction M23 are 99 degrees. Although omitted in illustration, both the first magnetization direction m21 and the third magnetization direction m23 are 99 degrees.

FIG. 15 is a waveform chart showing a waveform of each of the first and second detection signals S1 and S2 in the third modification example. In FIG. 15, the horizontal axis indicates the rotation angle θM of the motor 70, and the vertical axis indicates the magnitude of each of the first and second detection signals S1 and S2. In FIG. 15, the reference symbol 491 represents the first detection signal S1, and the reference symbol 492 represents the second detection signal S2. Further, FIG. 15 shows a range in which the rotation angle θM is 0 degrees or more and 600 degrees or less.

Within the range of the rotation angle θM shown in FIG. 15, the value of the first detection signal S1 is more than the value of the reference voltage (0 on the vertical axis of FIG. 15) when the rotation angle θM corresponds to the first case where 148.8 degrees<θM<326.9 degrees or 508.8 degrees<θM≤600 degrees is satisfied, and is less than the value of the reference voltage when the rotation angle θM corresponds to the second case where 0 degrees≤θM<148.8 degrees or 326.9 degrees<θM<508.8 degrees is

satisfied. Therefore, within the range described above, the first comparator 21 (see FIG. 4) outputs the High-level signal when the rotation angle θM corresponds to the first case, and outputs the Low-level signal when the rotation angle θM corresponds to the second case.

Within the range of the rotation angle θM shown in FIG. 15, the value of the second detection signal S2 is more than the value of the reference voltage when the rotation angle θM corresponds to a third case where 91.7 degrees<θM<269.8 degrees or 451.7 degrees<θM≤600 degrees is satisfied, and is less than the value of the reference voltage when the rotation angle θM corresponds to a fourth case where 0 degrees≤θM<91.7 degrees or 269.8 degrees<θM<451.7 degrees is satisfied. Therefore, within the range described above, the second comparator 22 (see FIG. 4) outputs the High-level signal when the rotation angle θM corresponds to the third case, and outputs the Low-level signal when the rotation angle θM corresponds to the fourth case.

Within the range of the rotation angle θM shown in FIG. 15, the value of the first detection signal S1 is more than the second detection signal S2 when the rotation angle θM corresponds to a fifth case where 0 degrees≤θM<29.9 degrees, 207.3 degrees<θM<389.9 degrees, or 567.3 degrees<θM≤600 degrees is satisfied, and is less than the value of the second detection signal S2 when the rotation angle θM corresponds to a sixth case where 29.9 degrees<θM<207.3 degrees or 389.9 degrees<θM<567.3 degrees is satisfied. Therefore, within the range described above, the third comparator 23 (see FIG. 4) outputs the High-level signal when the rotation angle θM corresponds to the fifth case, and outputs the Low-level signal when the rotation angle θM corresponds to the sixth case.

The point P1 shown in FIG. 15 is a point at which the magnitude of the first detection signal S1 and the magnitude of the second detection signal S2 are equal to each other, and a point at which the rotation angle θM is 29.9 degrees. The point P2 is a point at which the magnitude of the first detection signal S1 is 0 and a point at which the rotation angle θM is 148.8 degrees. The point P3 is a point at which the magnitude of the second detection signal S2 is 0 and a point at which the rotation angle θM is 269.8 degrees. The point P4 is a point at which the magnitude of the first detection signal S1 and the magnitude of the second detection signal S2 are equal to each other, and a point at which the rotation angle θM is 389.9 degrees. The point P5 is a point at which the magnitude of the first detection signal S1 is 0 and a point at which the rotation angle θM is 508.8 degrees.

In a temporal sub-period from the timing corresponding to the point P1 to the timing corresponding to the point P2, the rotation angle θM changes by 118.9 degrees. In a temporal sub-period from the timing corresponding to the point P2 to the timing corresponding to the point P3, the rotation angle θM changes by 121.0 degrees. In a temporal sub-period from the timing corresponding to the point P3 to the timing corresponding to the point P4, the rotation angle θM changes by 120.1 degrees. In a temporal sub-period from the timing corresponding to the point P4 to the timing corresponding to the point P5, the rotation angle θM changes by 118.9 degrees.

### Second Example Embodiment

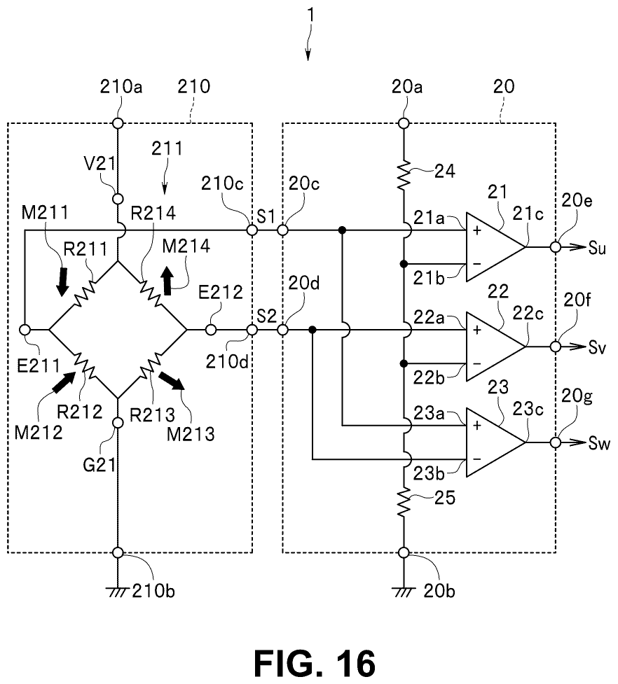

Next, a second example embodiment of the disclosure is described. First, with reference to FIG. 16, a configuration of the magnetic sensor 1 according to the example embodiment is described. FIG. 16 is a circuit diagram showing a circuit configuration of the magnetic sensor 1.

The magnetic sensor 1 according to the example embodiment includes a detection circuit 210 in place of the detection circuit 10 in the first example embodiment. The detection circuit 210 is configured to detect the rotating magnetic field MF and output the first detection signal S1 and the second detection signal S2.

The detection circuit 210 includes a bridge circuit 211 including a first resistor section R211, a second resistor section R212, a third resistor section R213, and a fourth resistor section R214 that include the plurality of MR elements 50. The bridge circuit 211 further includes a power supply port V21, a ground port G21, a first output port E211, and a second output port E212.

As shown in FIG. 16, the first resistor section R211 is provided between the power supply port V21 and the first output port E211 in the circuit configuration. The second resistor section R212 is provided between the ground port G21 and the first output port E211 in the circuit configuration. The third resistor section R213 is provided between the ground port G21 and the second output port E212 in the circuit configuration. The fourth resistor section R214 is provided between the power supply port V21 and the second output port E212 in the circuit configuration.

The detection circuit 210 further includes a power supply terminal 210a, a ground terminal 210b, a first output terminal 210c, a second output terminal 210d, and a bridge circuit 211. The power supply port V21 is connected to the power supply terminal 210a. The ground port G21 is connected to the ground terminal 210b. A voltage or current of a specific magnitude is applied to the power supply terminal 210a. The ground terminal 210b is grounded.

The first output port E211 is connected to the first output terminal 210 c. The bridge circuit 211 generates a signal corresponding to a potential of the first output port E211 as the first detection signal S1. The first output terminal 210c outputs the first detection signal S1.

The second output port E212 is connected to the second output terminal 210d. The bridge circuit 211 generates a signal corresponding to a potential of the second output port E212 as the second detection signal S2. The second output terminal 210d outputs the second detection signal S2.

The first output terminal 210c is connected to the first input terminal 20c of the logic signal generation circuit 20. The second output terminal 210d is connected to the second input terminal 20d of the logic signal generation circuit 20.

Next, with reference to FIG. 16, description is made on the magnetization direction of the magnetization pinned layer 52 in each of the first to fourth resistor sections R211 to R214 of the bridge circuit 211 and sensitivity of each of the first to fourth resistor sections R11 to R14. In the example embodiment, the plurality of MR elements 50 includes a plurality of first MR elements 50A3 constituting the first resistor section R211, a plurality of second MR elements 50B3 constituting the second resistor section R212, a plurality of third MR elements 50C3 constituting the third resistor section R213, and a plurality of fourth MR elements 50D3 constituting the fourth resistor section R214.

Here, a direction obtained by averaging the magnetization directions of the plurality of magnetization pinned layers 52 included in the plurality of first MR elements 50A3 is referred to as a first magnetization direction m211, a direction obtained by averaging the magnetization directions of the plurality of magnetization pinned layers 52 included in the plurality of second MR elements 50B3 is referred to as a second magnetization direction m212, a direction obtained by averaging the magnetization directions of the plurality of magnetization pinned layers 52 included in the plurality of third MR elements 50C3 is referred to as a third magnetization direction m213, and a direction obtained by averaging the magnetization directions of the plurality of magnetization pinned layers 52 included in the plurality of fourth MR elements 50D3 is referred to as a fourth magnetization direction m214.

The first resistor section R211 has sensitivity in a first direction parallel to a first reference direction M211. The second resistor section R212 has sensitivity in a second direction parallel to a second reference direction M212. The third resistor section R213 has sensitivity in a third direction parallel to a third reference direction M213. The fourth resistor section R214 has sensitivity in a fourth direction parallel to a fourth reference direction M214. In FIG. 16, the first to fourth reference directions M211 to M214 are indicated by the arrows denoted with the reference symbols M211 to M214, respectively. The first reference direction M211 matches with the first magnetization direction m211, the second reference direction M212 matches with the second magnetization direction m212, the third reference direction M213 matches with the third magnetization direction m213, and the fourth reference direction M214 matches with the fourth magnetization direction m214.

As shown in FIG. 16, the first reference direction M211 is 266 degrees, the second reference direction M212 is 42 degrees, the third reference direction M213 is 328 degrees, and the fourth reference direction M214 is 92 degrees. Although omitted in illustration, the first magnetization direction m211 is 266 degrees, the second magnetization direction m212 is 42 degrees, the third magnetization direction m213 is 328 degrees, and the fourth magnetization direction m214 is 92 degrees.

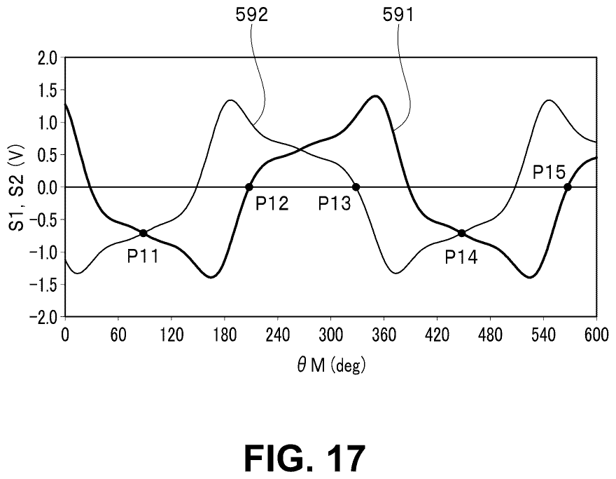

Next, with reference to FIG. 17, the first and second detection signals S1 and S2, and the first to third logic signals Su, Sv, and Sw in the example embodiment are described. FIG. 17 is a waveform chart showing a waveform of each of the first and second detection signals S1 and S2. In FIG. 17, the horizontal axis indicates the rotation angle θM of the motor 70, and the vertical axis indicates the magnitude of each of the first and second detection signals S1 and S2. In FIG. 17, the reference symbol 591 represents the first detection signal S1, and the reference symbol 592 represents the second detection signal S2. Further, FIG. 17 shows a range in which the rotation angle θM is 0 degrees or more and 600 degrees or less.

Within the range of the rotation angle θM shown in FIG. 17, the value of the first detection signal S1 is more than the value of the reference voltage (0 on the vertical axis of FIG. 17) when the rotation angle θM corresponds to a first case where 0 degrees≤θM<28.2 degrees, 208.3 degrees<θM<388.2 degrees, or 568.3 degrees<θM≤600 degrees is satisfied, and is less than the value of the reference voltage when the rotation angle θM corresponds to a second case where 28.2 degrees<θM<208.3 degrees or 388.2 degrees<θM<568.3 degrees is satisfied. Therefore, within the range described above, the first comparator 21 outputs the High-level signal when the rotation angle θM corresponds to the first case, and outputs the Low-level signal when the rotation angle θM corresponds to the second case.

Within the range of the rotation angle θM shown in FIG. 17, the value of the second detection signal S2 is more than the value of the reference voltage when the rotation angle θM corresponds to a third case where 149 degrees<θM<328.9 degrees or 509 degrees<θM≤600 degrees is satisfied, and is less than the value of the reference voltage when the rotation angle θM corresponds to a fourth case where 0 degrees≤θM<149 degrees or 328.9 degrees<θM<509 degrees is satisfied. Therefore, within the range described above, the second comparator 22 outputs the High-level signal when the rotation angle θM corresponds to the third case, and outputs the Low-level signal when the rotation angle θM corresponds to the fourth case.

Within the range of the rotation angle θM shown in FIG. 17, the value of the first detection signal S1 is more than the second detection signal S2 when the rotation angle θM corresponds to a fifth case where 0 degrees≤θM<88.3 degrees or 265.7 degrees<θM<448.3 degrees is satisfied, and is less than the value of the second detection signal S2 when the rotation angle θM corresponds to a sixth case where 88.3 degrees<θM<265.7 degrees or 448.3 degrees<θM≤600 degrees is satisfied. Therefore, within the range described above, the third comparator 23 outputs the High-level signal when the rotation angle θM corresponds to the fifth case, and outputs the Low-level signal when the rotation angle θM corresponds to the sixth case.

A point P11 shown in FIG. 17 is a point at which the magnitude of the first detection signal S1 and the magnitude of the second detection signal S2 are equal to each other, and a point at which the rotation angle θM is 88.3 degrees. A point P12 is a point at which the magnitude of the first detection signal S1 is 0 and a point at which the rotation angle θM is 208.3 degrees. A point P13 is a point at which the magnitude of the second detection signal S2 is 0 and a point at which the rotation angle θM is 328.9 degrees. A point P14 is a point at which the magnitude of the first detection signal S1 and the magnitude of the second detection signal S2 are equal to each other, and a point at which the rotation angle θM is 448.3 degrees. A point corresponding to a point P15 is a point at which the magnitude of the first detection signal S1 is 0 and a point at which the rotation angle θM is 568.3 degrees.

In a temporal sub-period from the timing corresponding to the point P11 to the timing corresponding to the point P12, the rotation angle θM changes by 120.0 degrees. In a temporal sub-period from the timing corresponding to the point P12 to the timing corresponding to the point P13, the rotation angle θM changes by 120.6 degrees. In a temporal sub-period from the timing corresponding to the point P13 to the timing corresponding to the point P14, the rotation angle θM changes by 119.4 degrees. In a temporal sub-period from the timing corresponding to the point P14 to the timing corresponding to the point P15, the rotation angle θM changes by 120.0 degrees.

The other configurations, operation and effects of the present example embodiment are otherwise the same as those of the first example embodiment.

Note that the disclosure is not limited to the foregoing example embodiments, and various modifications can be made. For example, each of the magnetization directions may be set to various directions as long as the requirements of the claims are satisfied. A specific direction of each of the magnetization directions can be explored by the designing method of the disclosure.

At least a part of the control circuit 121 and the logic signal generation circuit 20 may be implemented by an ASIC or a microcomputer.

As described above, a magnetic sensor according to one embodiment of the disclosure includes at least one bridge circuit and a plurality of magnetoresistive elements. The at least one bridge circuit includes a first port, a second port, a third port, a fourth port, a first resistor section provided between the first port and the second port, a second resistor section provided between the second port and the third port, a third resistor section provided between the third port and the fourth port, and a fourth resistor section provided between the fourth port and the first port. Each of the plurality of magnetoresistive elements includes a magnetization pinned layer having a magnetization whose direction is fixed and a free layer having a magnetization whose direction is variable depending on a magnetic field to be applied. The plurality of magnetoresistive elements includes a plurality of first magnetoresistive elements constituting the first resistor section, a plurality of second magnetoresistive elements constituting the second resistor section, a plurality of third magnetoresistive elements constituting the third resistor section, and a plurality of fourth magnetoresistive elements constituting the fourth resistor section. The first resistor section, the second resistor section, and the third resistor section are configured so that a first magnetization direction, a second magnetization direction, and a third magnetization direction intersect with one another at angles other than 0 degrees and 180 degrees, the first magnetization direction being a direction obtained by averaging magnetization directions of the plurality of magnetization pinned layers included in the plurality of first magnetoresistive elements, the second magnetization direction being a direction obtained by averaging magnetization directions of the plurality of magnetization pinned layers included in the plurality of second magnetoresistive elements, the third magnetization direction being a direction obtained by averaging magnetization directions of the plurality of magnetization pinned layers included in the plurality of third magnetoresistive elements.

In the magnetic sensor according to one embodiment of the disclosure, the first resistor section, the second resistor section, and the third resistor section may have sensitivity in a first direction, sensitivity in a second direction, and sensitivity in a third direction, respectively. The first resistor section, the second resistor section, and the third resistor section may be configured so that the first direction, the second direction, and the third direction intersect with one another at angles other than 0 degrees and 180 degrees.

In the magnetic sensor according to one embodiment of the disclosure, the fourth resistor section may be configured so that a fourth magnetization direction intersects with the first magnetization direction, the second magnetization direction, and the third magnetization direction at angles other than 0 degrees and 180 degrees, the fourth magnetization direction being a direction obtained by averaging magnetization directions of the plurality of magnetization pinned layers included in the plurality of fourth magnetoresistive elements.

In the magnetic sensor according to one embodiment of the disclosure, the at least one bridge circuit may include two bridge circuits. The fourth resistor section of at least one of the two bridge circuits may be configured so that a fourth magnetization direction intersects with each of the first magnetization direction, the second magnetization direction, and the third magnetization direction at angles other than 0 degrees and 180 degrees, the fourth magnetization direction being a direction obtained by averaging magnetization directions of the plurality of magnetization pinned layers included in the plurality of fourth magnetoresistive elements.

In the magnetic sensor according to one embodiment of the disclosure, the fourth resistor section may be configured so that a fourth magnetization direction is the same as any one of the first magnetization direction, the second magnetization direction, and the third magnetization direction, the fourth magnetization direction being a direction obtained by averaging magnetization directions of the plurality of magnetization pinned layers included in the plurality of fourth magnetoresistive elements.

The magnetic sensor according to one embodiment of the disclosure may further include a main body in which the at least one bridge circuit is embedded.

In the magnetic sensor according to one embodiment of the disclosure, the at least one bridge circuit may be configured to detect a rotating magnetic field whose direction rotates at a detection position and to generate a first detection signal and a second detection signal each corresponding to a change of the direction of the magnetic field, and may be configured so that a temporal period corresponding to one rotation in the direction of the rotating magnetic field is divided into three or more temporal sub-periods, based on the first detection signal and the second detection signal. The at least one bridge circuit may be configured so that the sub-periods correspond to a change in the direction of the magnetic field within 120 degrees ±10 degrees. The magnetic sensor of the disclosure may further include a logic signal generation circuit configured to generate a first logic signal, a second logic signal, and a third logic signal having respective different phases by using the first detection signal and the second detection signal.

A motor device according to one embodiment of the disclosure includes a motor, a driving circuit for the motor, and the magnetic sensor according to the one embodiment of the disclosure. The magnetic sensor is connected to the driving circuit.

A method for manufacturing a magnetic sensor according to one embodiment of the disclosure includes an element formation step of forming the plurality of magnetoresistive elements. The element formation step includes a step of forming a stacked film including a plurality of first magnetic sections that later serve as a plurality of magnetization pinned layers and a plurality of second magnetic sections that later serve as a plurality of free layers and a fixation step of fixing a magnetization direction of each of the plurality of first magnetic sections by using laser light and an external magnetic field. The fixation step includes a first step of fixing magnetization directions of a plurality of first specific magnetic sections, among the plurality of first magnetic sections, which later serve as a plurality of magnetization pinned layers of the plurality of first magnetoresistive elements, a second step of fixing magnetization directions of a plurality of second specific magnetic sections, among the plurality of first magnetic sections, which later serve as a plurality of magnetization pinned layers of the plurality of second magnetoresistive elements, and a third step of fixing magnetization directions of a plurality of third specific magnetic sections, among the plurality of first magnetic sections, which later serve as a plurality of magnetization pinned layers of the plurality of third magnetoresistive elements. A direction of the external magnetic field in the first step, a direction of the external magnetic field in the second step, and a direction of the external magnetic field in the third step intersect with one another at angles other than 0 degrees and 180 degrees.

A magnetic sensor that is designed by a designing method according to one embodiment of the disclosure includes a bridge circuit and a plurality of magnetoresistive elements. The bridge circuit includes a first port, a second port, a third port, a fourth port, a first resistor section provided between the first port and the second port, a second resistor section provided between the second port and the third port, a third resistor section provided between the third port and the fourth port, and a fourth resistor section provided between the fourth port and the first port. Each of the plurality of magnetoresistive elements includes a magnetization pinned layer having a magnetization whose direction is fixed and a free layer having a magnetization whose direction is variable depending on a magnetic field to be applied. The plurality of magnetoresistive elements includes a plurality of first magnetoresistive elements constituting the first resistor section, a plurality of second magnetoresistive elements constituting the second resistor section, a plurality of third magnetoresistive elements constituting the third resistor section, and a plurality of fourth magnetoresistive elements constituting the fourth resistor section. The bridge circuit is configured to detect a rotating magnetic field whose direction rotates at a detection position.

The designing method according to one embodiment of the disclosure includes setting directions of magnetizations of a plurality of magnetization pinned layers included in each of the plurality of first magnetoresistive elements, the plurality of second magnetoresistive elements, the plurality of third magnetoresistive elements, and the plurality of fourth magnetoresistive elements so that the bridge circuit generates a first detection signal and a second detection signal each corresponding to a change of the direction of the rotating magnetic field, and setting the directions of the magnetizations of the plurality of magnetization pinned layers so that a temporal period corresponding to one rotation in the direction of the rotating magnetic field is divided into three or more temporal sub-periods, based on the first detection signal and the second detection signal.

In the disclosure, the first magnetization direction, the second magnetization direction, and the third magnetization direction intersect with one another at angles other than 0 degrees and 180 degrees. With this, according to the disclosure, a magnetic sensor capable of generating a detection signal that can be used for rotation control of a motor can be achieved.

Obviously, many modifications and variations of the disclosure are possible in the light of the above teachings. Thus, it is to be understood that, within the scope of the appended claims and equivalents thereof, the disclosure may be practiced in other example embodiments than the foregoing example embodiments.

1. A magnetic sensor comprising:
at least one bridge circuit; and
a plurality of magnetoresistive elements, wherein
the at least one bridge circuit includes
a first port,
a second port,
a third port,
a fourth port,
a first resistor section provided between the first port and the second port,
a second resistor section provided between the second port and the third port,
a third resistor section provided between the third port and the fourth port, and
a fourth resistor section provided between the fourth port and the first port,
each of the plurality of magnetoresistive elements includes a magnetization pinned layer having a magnetization whose direction is fixed and a free layer having a magnetization whose direction is variable depending on a magnetic field to be applied,
the plurality of magnetoresistive elements includes a plurality of first magnetoresistive elements constituting the first resistor section, a plurality of second magnetoresistive elements constituting the second resistor section, a plurality of third magnetoresistive elements constituting the third resistor section, and a plurality of fourth magnetoresistive elements constituting the fourth resistor section, and
the first resistor section, the second resistor section, and the third resistor section are configured so that a first magnetization direction, a second magnetization direction, and a third magnetization direction intersect with one another at angles other than 0 degrees and 180 degrees, the first magnetization direction being a direction obtained by averaging magnetization directions of the plurality of magnetization pinned layers included in the plurality of first magnetoresistive elements, the second magnetization direction being a direction obtained by averaging magnetization directions of the plurality of magnetization pinned layers included in the plurality of second magnetoresistive elements, the third magnetization direction being a direction obtained by averaging magnetization directions of the plurality of magnetization pinned layers included in the plurality of third magnetoresistive elements.

2. The magnetic sensor according to claim 1, wherein
the first resistor section, the second resistor section, and the third resistor section has sensitivity in a first direction, sensitivity in a second direction, and sensitivity in a third direction, respectively, and
the first resistor section, the second resistor section, and the third resistor section are configured so that the first direction, the second direction, and the third direction intersect with one another at angles other than 0 degrees and 180 degrees.

3. The magnetic sensor according to claim 1, wherein
the fourth resistor section is configured so that a fourth magnetization direction intersects with the first magnetization direction, the second magnetization direction, and the third magnetization direction at angles other than 0 degrees and 180 degrees, the fourth magnetization direction being a direction obtained by averaging magnetization directions of the plurality of magnetization pinned layers included in the plurality of fourth magnetoresistive elements.

4. The magnetic sensor according to claim 1, wherein
the at least one bridge circuit includes two bridge circuits, and
the fourth resistor section of at least one of the two bridge circuits is configured so that a fourth magnetization direction intersects with each of the first magnetization direction, the second magnetization direction, and the third magnetization direction at angles other than 0 degrees and 180 degrees, the fourth magnetization direction being a direction obtained by averaging magnetization directions of the plurality of magnetization pinned layers included in the plurality of fourth magnetoresistive elements.

5. The magnetic sensor according to claim 1, wherein
the fourth resistor section is configured so that a fourth magnetization direction is the same as any one of the first magnetization direction, the second magnetization direction, and the third magnetization direction, the fourth magnetization direction being a direction obtained by averaging magnetization directions of the plurality of magnetization pinned layers included in the plurality of fourth magnetoresistive elements.

6. The magnetic sensor according to claim 1, further comprising
a main body in which the at least one bridge circuit is embedded.

7. The magnetic sensor according to claim 1, wherein
the at least one bridge circuit is configured to detect a rotating magnetic field whose direction rotates at a detection position and to generate a first detection signal and a second detection signal each corresponding to a change of the direction of the magnetic field, and is configured so that a temporal period corresponding to one rotation in the direction of the rotating magnetic field is divided into three or more temporal sub-periods, based on the first detection signal and the second detection signal.

8. The magnetic sensor according to claim 7, wherein
the at least one bridge circuit is configured so that the sub-periods correspond to a change in the direction of the magnetic field within 120 degrees ±10 degrees.

9. The magnetic sensor according to claim 7, further comprising
a logic signal generation circuit configured to generate a first logic signal, a second logic signal, and a third logic signal having respective different phases by using the first detection signal and the second detection signal.

10. A motor device comprising:
a motor;
a driving circuit for the motor;
the magnetic sensor according to claim 1, wherein
the magnetic sensor is connected to the driving circuit.

11. A method for manufacturing the magnetic sensor according to claim 1, the method comprising:
an element formation step of forming the plurality of magnetoresistive elements, wherein
the element formation step includes:
a step of forming a stacked film including a plurality of first magnetic sections that later serve as a plurality of magnetization pinned layers and a plurality of second magnetic sections that later serve as a plurality of free layers; and
a fixation step of fixing a magnetization direction of each of the plurality of first magnetic sections by using laser light and an external magnetic field, the fixation step includes:
a first step of fixing magnetization directions of a plurality of first specific magnetic sections, among the plurality of first magnetic sections, which later serve as a plurality of magnetization pinned layers of the plurality of first magnetoresistive elements;
a second step of fixing magnetization directions of a plurality of second specific magnetic sections, among the plurality of first magnetic sections, which later serve as a plurality of magnetization pinned layers of the plurality of second magnetoresistive elements; and
a third step of fixing magnetization directions of a plurality of third specific magnetic sections, among the plurality of first magnetic sections, which later serve as a plurality of magnetization pinned layers of the plurality of third magnetoresistive elements, and
a direction of the external magnetic field in the first step, a direction of the external magnetic field in the second step, and a direction of the external magnetic field in the third step intersect with one another at angles other than 0 degrees and 180 degrees.

12. A method for designing a magnetic sensor including a bridge circuit and a plurality of magnetoresistive elements, wherein
the bridge circuit includes:
a first port;
a second port;
a third port;
a fourth port;
a first resistor section provided between the first port and the second port;
a second resistor section provided between the second port and the third port;
a third resistor section provided between the third port and the fourth port; and
a fourth resistor section provided between the fourth port and the first port,
each of the plurality of magnetoresistive elements includes a magnetization pinned layer having a magnetization whose direction is fixed and a free layer having a magnetization whose direction is variable depending on a magnetic field to be applied,
the plurality of magnetoresistive elements includes a plurality of first magnetoresistive elements constituting the first resistor section, a plurality of second magnetoresistive elements constituting the second resistor section, a plurality of third magnetoresistive elements constituting the third resistor section, and a plurality of fourth magnetoresistive elements constituting the fourth resistor section,
the bridge circuit is configured to detect a rotating magnetic field whose direction rotates at a detection position, and
the method of designing comprising:
setting directions of magnetizations of a plurality of magnetization pinned layers included in each of the plurality of first magnetoresistive elements, the plurality of second magnetoresistive elements, the plurality of third magnetoresistive elements, and the plurality of fourth magnetoresistive elements so that the bridge circuit generates a first detection signal and a second detection signal each corresponding to a change of the direction of the rotating magnetic field; and
setting the directions of the magnetizations of the plurality of magnetization pinned layers so that a temporal period corresponding to one rotation in the direction of the rotating magnetic field is divided into three or more temporal sub-periods, based on the first detection signal and the second detection signal.
